(19) United States
(12) Patent Application Publication
(10) Pub. No.: US 2023/0102430 A1
(43) Pub. Date: Mar. 30, 2023

(54) LIGHT SOURCE MODULE

(71) Applicant: HAMAMATSU PHOTONICS K.K., Hamamatsu-shi, Shizuoka (JP)

(72) Inventors: Yoshitaka KUROSAKA, Hamamatsu-shi, Shizuoka (JP); Kazuyoshi HIROSE, Hamamatsu-shi, Shizuoka (JP); Soh UENOYAMA, Hamamatsu-shi, Shizuoka (JP)

(73) Assignee: HAMAMATSU PHOTONICS K.K., Hamamatsu-shi, Shizuoka (JP)

(21) Appl. No.: 17/792,181

(22) PCT Filed: Jan. 15, 2021
(86) PCT No.: PCT/JP2021/001315

§ 371 Date: Jul. 12, 2022

(30) Foreign Application Priority Data
Jan. 20, 2020 (JP) 2020-006906
Jan. 20, 2020 (JP) 2020-006907
Sep. 25, 2020 (JP) 2020-160719

(51) Int. Cl. H01S 5/11; H01S 5/042

(52) U.S. Cl. CPC H01S 5/11; H01S 5/04256; H01S 5/04254

(57) ABSTRACT

An embodiment relates to a light source module dynamically controlling a phase distribution of light. The light source module includes a semiconductor stack portion. The semiconductor stack portion includes a stacked body including an active layer and a photonic crystal layer causing Γ-point oscillation, and includes a phase synchronization portion and an intensity modulation portion which are arranged in a Y-direction as one resonance direction of the photonic crystal layer. The stacked body in the intensity modulation portion has M (≥2) pixels each arranged in an X-direction and including N₁ (≥2) subpixels. A length of a region including consecutive N₂ (≥2, ≤N₁) subpixels among the N₁ subpixels, defined in the X-direction, is smaller than an emission wavelength of the active layer. The light source module outputs laser light from each M pixel included in the intensity modulation portion in a direction intersecting both X- and Y-directions.

### TECHNICAL FIELD

The present disclosure relates to a light source module.

The present application claims the benefit of priority under Japanese Patent Application No. 2020-006906, filed on Jan. 20, 2020, Japanese Patent Application No. 2020-006907, filed on Jan. 20, 2020, and Japanese Patent Application No. 2020-160719, filed on Sep. 25, 2020, the contents of each of which are relied upon and incorporated herein by reference in their entireties.

### BACKGROUND ART

Patent Document 1 discloses a technique related to an edge-emitting semiconductor laser element. This semiconductor laser element includes a lower cladding layer formed on a substrate, an upper cladding layer, an active layer interposed between the lower cladding layer and the upper cladding layer, a photonic crystal layer interposed at least between the active layer and the upper cladding layer or between the active layer and the lower cladding layer, and a first drive electrode for supplying a drive current to a first region of the active layer. A longitudinal direction of the first drive electrode is inclined with respect to a normal line of a light output end face of the semiconductor laser element when viewed from a thickness direction of the semiconductor laser element. A region corresponding to the first region of the photonic crystal layer has first and second periodic structures in which arrangement periods of different refractive index portions having refractive indexes different from surroundings are different from each other. Two or more laser beams forming a predetermined angle with respect to the longitudinal direction of the first drive electrode are generated inside the semiconductor laser element according to a difference between the reciprocals of the arrangement periods in the first and second periodic structures. Among these laser beams, a refraction angle of one laser beam directed to the light output end face with respect to the light output end face is less than 90 degrees. The other at least one laser beam directed to the light output end face meets a total reflection critical angle condition with respect to the light output end face.

Non-Patent Document 1 discloses a technique related to a computer-generated hologram (CGH). One pixel is constituted by four subpixels each having an independent reflectance, which are created by printing, and reflected laser light beams emitted to a plurality of pixels are combined. In this case, Non-Patent Document 1 describes that a light emission direction from each pixel can be arbitrarily shifted. Non-Patent Document 2 describes that, in the technique described in Non-Patent Document 1, when each pixel includes three subpixels each having an independent reflectance, the light emission direction from each pixel can be arbitrarily shifted.

### CITATION LIST

### Patent Literature

Patent Document 1: Japanese Patent Application Laid-Open No. 2013-120801

### Non-Patent Literature

Non-Patent Document 1: Wai Hon Lee, “Sampled Fourier Transform Hologram Generated by Computer,” Applied Optics, Vol. 9, No. 3, pp. 639-643, March 1970
Non-Patent Document 2: C. B. Burckhardt, “A Simplification of Lee's Method of Generating Holograms by Computer,” Applied Optics, Vol. 9, No. 8, p. 1949, August 1970
Non-Patent Document 3: Y. Kurosaka et al., “Effects of non-lasing band in two-dimensional photonic-crystal lasers clarified using omnidirectional band structure,” Opt. Express 20, 21773-21783 (2012)

### SUMMARY OF INVENTION

### Technical Problem

As a result of studying the above-described technique of the related art, the inventors have found the following problems. That is, in the related art, a technique of changing a light traveling direction or generating an arbitrary optical image by performing spatial phase modulation have been studied. In a certain technique, a phase modulation layer including a plurality of modified refractive index regions is provided in the vicinity of an active layer of a semiconductor laser element. Then, in a virtual square lattice set on a plane perpendicular to a thickness direction of the phase modulation layer, for example, with respect to a plurality of the modified refractive index regions, the gravity center of each of the modified refractive index regions is disposed at a position away from a lattice point of the virtual square lattice, and an angle of a vector connecting the corresponding lattice point with the gravity center with respect to the virtual square lattice is individually set. Like a photonic crystal laser element, such an element can output laser light beam in a stacking direction, spatially control a phase distribution of the laser light beam, and output the laser light beam as an arbitrary optical image.

However, in the above-described element, since the arrangement of a plurality of the modified refractive index regions of the phase modulation layer is fixed, only one optical image designed in advance can be outputted. In order to dynamically change the output optical image and the light traveling direction, it is necessary to dynamically control the phase distribution of the output light.

The present disclosure has been made to solve the above-described problems, and an object of the present disclosure is to provide a light source module capable of dynamically controlling a phase distribution of light.

### Solution to Problem

A light source module according to an aspect of the present disclosure includes a semiconductor stack portion, a first electrode, a second electrode, a third electrode, and a fourth electrode. The semiconductor stack portion includes a first conductivity type semiconductor layer, a second conductivity type semiconductor layer, and a stacked body including an active layer and a photonic crystal layer. The stacked body including the active layer and the photonic crystal layer is disposed between the first conductivity type semiconductor layer and the second conductivity type semiconductor layer. The photonic crystal layer causes oscillation at a Γ point. The semiconductor stack portion includes a phase synchronization portion and an intensity modulation portion which are arranged in a first direction which is one of resonance directions of the photonic crystal layer. A portion of the stacked body constituting at least a part of the intensity modulation portion has M (M is an integer of two or more) pixels arranged in a second direction intersecting the first direction. Each of the M pixels includes N₁ (N₁ is an integer of two or more) subpixels arranged in the second direction. A length of a region including consecutive N₂ (N₂ is an integer of two or more and N₁ or less) subpixels among the N₁ subpixels, which is defined in the second direction, is smaller than an emission wavelength λ of the active layer. The first electrode is electrically connected to a portion of the first conductivity type semiconductor layer constituting at least a part of the phase synchronization portion. The second electrode is electrically connected to a portion of the second conductivity type semiconductor layer constituting at least a part of the phase synchronization portion. The third electrode is provided in one-to-one correspondence with the N₁ subpixels, and is electrically connected to one of a portion of the first conductivity type semiconductor layer and a portion of the second conductivity type semiconductor layer which constitute at least a part of the intensity modulation portion. The fourth electrode is electrically connected to the other one of the portion of the first conductivity type semiconductor layer and the portion of the second conductivity type semiconductor layer which constitute at least a part of the intensity modulation portion. The light source module outputs light from each of the M pixels included in the intensity modulation portion in a direction intersecting both the first direction and the second direction.

A light source module according to another aspect of the present disclosure includes a semiconductor stack portion, a first electrode, a second electrode, a third electrode, and a fourth electrode. The semiconductor stack portion includes a first conductivity type semiconductor layer, a second conductivity type semiconductor layer, and a stacked body including an active layer and a resonance mode forming layer. The stacked body including the active layer and the resonance mode forming layer is disposed between the first conductivity type semiconductor layer and the second conductivity type semiconductor layer. The semiconductor stack portion includes a phase synchronization portion and an intensity modulation portion which are arranged in a first direction which is one of resonance directions of the resonance mode forming layer. A portion of the stacked body constituting at least a part of the intensity modulation portion has M (M is an integer of two or more) pixels arranged in a second direction intersecting the first direction. Each of the M pixels includes N₁ (N₁ is an integer of two or more) subpixels arranged in the second direction. A length of a region including consecutive N₂ (N₂ is an integer of two or more and N₁ or less) subpixels among the N₁ subpixels, which is defined in the second direction, is smaller than an emission wavelength λ of the active layer. The first electrode is electrically connected to a portion of the first conductivity type semiconductor layer constituting at least a part of the phase synchronization portion. The second electrode is electrically connected to a portion of the second conductivity type semiconductor layer constituting at least a part of the phase synchronization portion. The third electrode is provided in one-to-one correspondence with the N₁ subpixels, and is electrically connected to one of a portion of the first conductivity type semiconductor layer and a portion of the second conductivity type semiconductor layer which constitute at least a part of the intensity modulation portion. The fourth electrode is electrically connected to the other one of the portion of the first conductivity type semiconductor layer and the portion of the second conductivity type semiconductor layer which constitute at least a part of the intensity modulation portion. The resonance mode forming layer includes a base layer and a plurality of modified refractive index regions having a refractive index different from a refractive index of the base layer and distributed two-dimensionally on a plane perpendicular to a thickness direction of the resonance mode forming layer. The arrangement of a plurality of the modified refractive index regions satisfies a condition of M-point oscillation. In the portion of the resonance mode forming layer included in the intensity modulation portion, in the virtual square lattice set on the plane, the gravity center of each of a plurality of the modified refractive index regions is disposed in any one of a first mode and a second mode. In the first mode, the gravity center of each of a plurality of the modified refractive index regions is disposed away from the corresponding lattice point, and an angle of a vector connecting the corresponding lattice point with the gravity center with respect to the virtual square lattice is individually set. In the second mode, the gravity center of each of a plurality of the modified refractive index regions is disposed on a straight line passing through the lattice point of the virtual square lattice and inclined with respect to the square lattice, and a distance between the gravity center of each of a plurality of the modified refractive index regions and the corresponding lattice point is individually set. The distribution of the angle of the vector in the first mode or the distribution of the distance in the second mode satisfies a condition for outputting light from the intensity modulation portion in a direction intersecting both the first direction and the second direction.

### Advantageous Effects of Invention

According to the present disclosure, it is possible to provide a light source module capable of dynamically controlling a phase distribution of light.

### BRIEF DESCRIPTION OF DRAWINGS

FIG. 1 is a plan view of a light source module according to an embodiment of the present disclosure.

FIG. 2 is a bottom view of the light source module according to the embodiment.

FIG. 3 is a view schematically illustrating a cross section taken along line III-III of FIG. 1.

FIG. 4 is a view schematically illustrating a cross section taken along line Iv-Iv of FIG. 1.

FIGS. 5A and 5B are diagrams for explaining Γ-point oscillation in a real space and a reciprocal lattice space, respectively.

FIGS. 6A to 6D are diagrams for explaining a step of manufacturing the light source module according to the embodiment.

FIGS. 7A to 7D are diagrams for explaining a step of manufacturing the light source module according to the embodiment.

FIGS. 8A to 8D are diagrams for explaining a step of manufacturing the light source module according to the embodiment.

FIGS. 9A to 9D are diagrams for explaining a step of manufacturing the light source module according to the embodiment.

FIGS. 10A to 10D are diagrams for explaining a step of manufacturing the light source module according to the embodiment.

FIGS. 11A to 11D are diagrams for explaining a step of manufacturing the light source module according to the embodiment.

FIGS. 12A to 12D are diagrams for explaining a step of manufacturing the light source module according to the embodiment.

FIGS. 13A and 13B are views illustrating a step of flip-chip mounting the light source module on a control circuit board.

FIG. 14 is a view schematically illustrating a cross section of a light source module as a first modification example.

FIGS. 15A to 15D are diagrams for explaining a step of manufacturing the light source module according to the first modification example.

FIGS. 16A to 16D are diagrams for explaining a step of manufacturing the light source module according to the first modification example.

FIGS. 17A to 17D are diagrams for explaining a step of manufacturing the light source module according to the first modification example.

FIGS. 18A to 18D are diagrams for explaining a step of manufacturing the light source module according to the first modification example.

FIGS. 19A to 19D are diagrams for explaining a step of manufacturing the light source module according to the first modification example.

FIGS. 20A to 20D are diagrams for explaining a step of manufacturing the light source module according to the first modification example.

FIGS. 21A to 21D are diagrams for explaining a step of manufacturing the light source module according to the first modification example.

FIGS. 22A and 22B are views illustrating a step of flip-chip mounting the light source module on a control circuit board.

FIG. 23 is a plan view of a light source module according to a second modification example.

FIG. 24 is a bottom view of the light source module according to the second modification example.

FIG. 25 is a plan view illustrating all of sizes and positional relationships of a modified refractive index region, a first electrode, a third electrode, and a slit at the same magnification as an example of the second modification example.

FIGS. 26A and 26B are diagrams for explaining an effect of a phase shift portion.

FIG. 27 is a plan view of a light source module according to a third modification example.

FIG. 28 is a bottom view of the light source module according to the third modification example.

FIG. 29 is a view schematically illustrating a cross section taken along line XXIX-XXIX of FIG. 27.

FIG. 30 is a view schematically illustrating a cross section taken along line XXX-XXX of FIG. 27.

FIGS. 31A and 31B are diagrams for explaining M-point oscillation in a real space and a reciprocal lattice space, respectively.

FIG. 32 is a plan view of a resonance mode forming layer of an intensity modulation portion.

FIG. 33 is an enlarged view of a unit constituent region.

FIG. 34 is a diagram for explaining coordinate transformation from spherical coordinates (r, θᵣₒₜ, θₜᵢₗₜ) to coordinates (ξ, η, ζ) in an X′Y′Z orthogonal coordinate system.

FIG. 35 is a plan view illustrating a reciprocal lattice space related to a phase modulation layer of a light emitting device that performs M-point oscillation.

FIG. 36 is a conceptual diagram explaining a state in which a diffraction vector is added to an in-plane wave number vector.

FIG. 37 is a diagram for schematically explaining a peripheral structure of a light line.

FIG. 38 is a diagram conceptually illustrating an example of a phase distribution φ₂ (x, y).

FIG. 39 is a conceptual diagram for explaining a state in which a diffraction vector is added to a vector obtained by removing a wave number spread from in-plane wave number vectors in four directions.

FIG. 40 is a plan view illustrating another mode of a resonance mode forming layer of an intensity modulation portion.

FIG. 41 is a diagram illustrating an arrangement of a modified refractive index region 14b in a resonance mode forming layer 14B.

FIG. 42 is a plan view of a light source module according to a fourth modification example.

FIG. 43 is a bottom view of the light source module.

FIGS. 44A to 44H are diagrams for explaining a technique described in Non-Patent Document 1.

FIGS. 45A and 45B are diagrams for explaining a technique described in Non-Patent Document 2.

### DESCRIPTION OF EMBODIMENTS

### Description of Embodiments of Present Invention

First, the contents of the embodiment of the present invention will be individually listed and described.

(1) A first light source module according to an aspect of the present disclosure includes a semiconductor stack portion, a first electrode, a second electrode, a third electrode, and a fourth electrode.

The semiconductor stack portion includes a first conductivity type semiconductor layer, a second conductivity type semiconductor layer, and a stacked body including an active layer and a photonic crystal layer. The stacked body including the active layer and the photonic crystal layer is disposed between the first conductivity type semiconductor layer and the second conductivity type semiconductor layer. The photonic crystal layer causes oscillation at a Γ point. The semiconductor stack portion includes a phase synchronization portion and an intensity modulation portion which are arranged in a first direction which is one of resonance directions of the photonic crystal layer. A portion of the stacked body constituting at least a part of the intensity modulation portion has M (M is an integer of two or more) pixels arranged in a second direction intersecting the first direction. Each of the M pixels includes N₁ (N₁ is an integer of two or more) subpixels arranged in the second direction. A length of a region including consecutive N₂ (N₂ is an integer of two or more and N₁ or less) subpixels among the N₁ subpixels, which is defined in the second direction, is smaller than an emission wavelength λ of the active layer. The first electrode is electrically connected to a portion of the first conductivity type semiconductor layer constituting at least a part of the phase synchronization portion. The second electrode is electrically connected to a portion of the second conductivity type semiconductor layer constituting at least a part of the phase synchronization portion. The third electrode is provided in one-to-one correspondence with the N₁ subpixels, and is electrically connected to one of a portion of the first conductivity type semiconductor layer and a portion of the second conductivity type semiconductor layer which constitute at least a part of the intensity modulation portion. The fourth electrode is electrically connected to the other one of the portion of the first conductivity type semiconductor layer and the portion of the second conductivity type semiconductor layer which constitute at least a part of the intensity modulation portion. The light source module outputs light from each of the M pixels included in the intensity modulation portion in a direction intersecting both the first direction and the second direction.

In the first light source module, when a current is supplied between the first electrode and the second electrode, and between the third electrode and the fourth electrode, the active layers included in the phase synchronization portion and the intensity modulation portion emit light. The light outputted from the active layer enters the photonic crystal layer, and resonates in two directions including the first direction, which are perpendicular to the thickness direction in the photonic crystal layer. This light becomes a phase-aligned coherent laser light beam in the photonic crystal layer of the phase synchronization portion.

Furthermore, since the photonic crystal layer included in the intensity modulation portion is arranged in the first direction with respect to the photonic crystal layer included in the phase synchronization portion, a phase of the laser light beam in the photonic crystal layer of each subpixel coincides with a phase of the laser light beam in the photonic crystal layer of the phase synchronization portion, and as a result, the phases of the laser light beams in the photonic crystal layer are aligned between the subpixels. Since the photonic crystal layer causes Γ-point oscillation, the phase-aligned laser light beam is outputted from each subpixel included in the intensity modulation portion in a direction intersecting both the first direction and the second direction (typically, the thickness direction of the intensity modulation portion).

The third electrode is provided in one-to-one correspondence with each subpixel. Therefore, the magnitude of the current supplied to the intensity modulation portion can be individually adjusted for each subpixel. That is, light intensity of the laser light beam outputted from the intensity modulation portion can be adjusted individually (independently) for each subpixel. Furthermore, in the first light source module, in each pixel, a length of the region including consecutive N₂ subpixels among the N₁ subpixels in the second direction (that is, the arrangement direction of the subpixels) is smaller than the emission wavelength λ, of the active layer, that is, the wavelength of the laser light beam. In a case where the subpixels that output light at the same time are limited to the consecutive N₂ subpixels among the N₁ subpixels constituting each pixel, each pixel can be regarded as a pixel having a single phase equivalently. In a case where the phases of the laser light beams outputted from the N₁ subpixels constituting each pixel are aligned with each other, the phase of the laser light beam outputted from each pixel is determined according to an intensity distribution realized by the N₁ subpixels constituting the pixel. Therefore, according to the first light source module, the phase distribution of the light can be dynamically controlled.

(2) A second light source module according to an aspect of the present disclosure includes a semiconductor stack portion, a first electrode, a second electrode, a third electrode, and a fourth electrode. The semiconductor stack portion includes a first conductivity type semiconductor layer, a second conductivity type semiconductor layer, and a stacked body including an active layer and a resonance mode forming layer. The stacked body including the active layer and the resonance mode forming layer is disposed between the first conductivity type semiconductor layer and the second conductivity type semiconductor layer. The semiconductor stack portion includes a phase synchronization portion and an intensity modulation portion which are arranged in a first direction which is one of resonance directions of the resonance mode forming layer. A portion of the stacked body constituting at least a part of the intensity modulation portion has M (M is an integer of two or more) pixels arranged in a second direction intersecting the first direction. Each of the M pixels includes N₁ (N₁ is an integer of two or more) subpixels arranged in the second direction. A length of a region including consecutive N₂ (N₂ is an integer of two or more and N₁ or less) subpixels among the N₁ subpixels, which is defined in the second direction, is smaller than an emission wavelength λ of the active layer. The first electrode is electrically connected to a portion of the first conductivity type semiconductor layer constituting at least a part of the phase synchronization portion. The second electrode is electrically connected to a portion of the second conductivity type semiconductor layer constituting at least a part of the phase synchronization portion. The third electrode is provided in one-to-one correspondence with the N₁ subpixels, and is electrically connected to one of a portion of the first conductivity type semiconductor layer and a portion of the second conductivity type semiconductor layer which constitute at least a part of the intensity modulation portion. The fourth electrode is electrically connected to the other one of the portion of the first conductivity type semiconductor layer and the portion of the second conductivity type semiconductor layer which constitute at least a part of the intensity modulation portion. The resonance mode forming layer includes a base layer and a plurality of modified refractive index regions having a refractive index different from a refractive index of the base layer and distributed two-dimensionally on a plane perpendicular to a thickness direction of the resonance mode forming layer. The arrangement of a plurality of the modified refractive index regions satisfies a condition of M-point oscillation. In the portion of the resonance mode forming layer included in the intensity modulation portion, in the virtual square lattice set on the plane, the gravity center of each of a plurality of the modified refractive index regions is disposed in any one of a first mode and a second mode. In the first mode, the gravity center of each of a plurality of the modified refractive index regions is disposed away from the corresponding lattice point, and an angle of a vector connecting the corresponding lattice point with the gravity center with respect to the virtual square lattice is individually set. In the second mode, the gravity center of each of a plurality of the modified refractive index regions is disposed on a straight line passing through the lattice point of the virtual square lattice and inclined with respect to the square lattice, and a distance between the gravity center of each of a plurality of the modified refractive index regions and the corresponding lattice point is individually set. The distribution of the angle of the vector in the first mode or the distribution of the distance in the second mode satisfies a condition for outputting light from the intensity modulation portion in a direction intersecting both the first direction and the second direction.

In the second light source module, when a current is supplied between the first electrode and the second electrode, and between the third electrode and the fourth electrode, the active layers of the phase synchronization portion and the intensity modulation portion emit light. The light outputted from the active layer enters the resonance mode forming layer, and resonates in two directions including the first direction, which are perpendicular to the thickness direction in the resonance mode forming layer. This light becomes a phase-aligned coherent laser light beam in the resonance mode forming layer of the phase synchronization portion. Furthermore, since each resonance mode forming layer of the intensity modulation portion divided into a plurality of the subpixels is arranged in the first direction with respect to the resonance mode forming layer of the phase synchronization portion, the phase of the laser light beam in the resonance mode forming layer of each subpixel coincides with the phase of the laser light beam in the resonance mode forming layer of the phase synchronization portion, and as a result, the phases of the laser light beams in the resonance mode forming layer are aligned between the subpixels.

The resonance mode forming layer of the second light source module causes the M-point oscillation, but in a portion of the resonance mode forming layer included in the intensity modulation portion, a distribution form of a plurality of the modified refractive index regions satisfies a condition for light to be outputted from the intensity modulation portion in a direction intersecting both the first direction and the second direction. Therefore, the phase-aligned laser light beam is outputted from each subpixel included in the intensity modulation portion in a direction intersecting both the first direction and the second direction.

The third electrode is provided in one-to-one correspondence with each subpixel. Therefore, the magnitude of the current supplied to the intensity modulation portion can be individually adjusted for each subpixel. That is, light intensity of the laser light beam outputted from the intensity modulation portion can be adjusted individually (independently) for each subpixel. Furthermore, also in the second light source module, in each pixel, a length of the region including consecutive N₂ subpixels among the N₁ subpixels in the second direction (that is, the arrangement direction of the subpixels) is smaller than the emission wavelength λ of the active layer, that is, the wavelength of the laser light beam. In a case where the subpixels that output light at the same time are limited to the consecutive N₂ subpixels among the N₁ subpixels constituting each pixel, each pixel can be regarded as a pixel having a single phase equivalently. In a case where the phases of the laser light beams outputted from the N₁ subpixels constituting each pixel are aligned with each other, the phase of the laser light beam outputted from each pixel is determined according to an intensity distribution realized by the N₁ subpixels constituting the pixel. Therefore, according to the second light source module, the phase distribution of the light can be dynamically controlled.

(3) As an aspect of the present disclosure, in the second light source module, a portion of the resonance mode forming layer included in the phase synchronization portion may have a photonic crystal structure in which a plurality of the modified refractive index regions are periodically disposed. In this case, the phase-aligned laser light beam can be supplied from the phase synchronization portion to each subpixel.

(4) As an aspect of the present disclosure, in the second light source module, a condition for light to be outputted in a direction intersecting both the first direction and the second direction from the intensity modulation portion may be that in-plane wave number vectors in four directions each including a wave number spread corresponding to angular spread of the light outputted from the intensity modulation portion are formed on an reciprocal lattice space of the resonance mode forming layer, and the magnitude of at least one in-plane wave number vector among the in-plane wave number vectors in four directions is smaller than 2π/λ.

(5) As an aspect of the present disclosure, in the first light source module, the photonic crystal layer may include a phase shift portion provided in one-to-one correspondence with the N₁ subpixels, the phase shift portion being configured to cause the phases of light outputted from each pixel in the first direction to be different from each other between the N₁ subpixels. Similarly, as an aspect of the present disclosure, in the second light source module, the resonance mode forming layer may include a phase shift portion provided in one-to-one correspondence with the N₁ subpixels, the phase shift portion being configured to cause the phases of light outputted from each pixel in the first direction to be different from each other between the N₁ subpixels. In this case, the phase of the laser light beam outputted from each pixel in the first direction is different for each subpixel. Therefore, the phase of the laser light beam outputted from each pixel in a direction intersecting both the first direction and the second direction is also different for each subpixel. The phase of the laser light beam outputted from each pixel is determined according to the intensity distribution and the phase distribution of the N₁ subpixels constituting the pixel. In this case, it is possible to dynamically modulate the phase distribution of the light in an output direction intersecting both the first direction and the second direction, and the degree of freedom of controlling the phase distribution of the light is further increased.

(6) As an aspect of the present disclosure, in the first and second light source modules, the first electrode may be in contact with the first conductivity type semiconductor layer and cover the entire surface of the portion of the first conductivity type semiconductor layer included in the phase synchronization portion. Furthermore, the second electrode may be in contact with the second conductivity type semiconductor layer and cover the entire surface of the second conductivity type semiconductor layer included in the phase synchronization portion. In this case, the laser light beam outputted from the phase synchronization portion in the stacking direction is shielded by the first electrode and the second electrode. In particular, in the first light source module, the photonic crystal layer of the phase synchronization portion causes Γ-point oscillation, and thus such shielding by the first electrode and the second electrode is effective.

(7) As an aspect of the present disclosure, in the first and second light source modules, the third electrode may be in contact with one of the portion of the first conductivity type semiconductor layer and the portion of the second conductivity type semiconductor layer which constitute at least a part of the intensity modulation portion. Furthermore, the fourth electrode may have a frame shape surrounding an opening for allowing light to pass, and may be in contact with the other one of the portion of the first conductivity type semiconductor layer and the portion of the second conductivity type semiconductor layer which constitute at least a part of the intensity modulation portion. In this case, while a sufficient current is supplied to the active layer of the intensity modulation portion, the laser light beam can be outputted from the intensity modulation portion in a direction intersecting both the first direction and the second direction.

(8) As an aspect of the present disclosure, in the first and second light source modules, the semiconductor stack portion may include a plurality of slits. The subpixels and a plurality of the slits are alternately arranged one by one in the second direction. In this case, the intensity modulation portion can be divided into a plurality of subpixels with a simple configuration.

(9) As an aspect of the present disclosure, in the first and second light source modules, both the number N₁ and the number N₂, which are described above, may be three or more. In this case, the phase of the laser light beam outputted from each pixel can be controlled in a range of 0° to 360°.

As described above, each aspect listed in the section of [Description of embodiments of present invention] is applicable to each of all the remaining aspects or to all combinations of these remaining aspects.

### Details of Embodiment of Present Invention

Hereinafter, a specific structure of the light source module according to the embodiment of the present disclosure will be described in detail with reference to the accompanying drawings. Note that the present invention is not limited to these examples, but is indicated by the claims, and is intended to include meanings equivalent to the claims and all modifications within the scope of the invention. Furthermore, in the description of the drawings, the same elements are denoted by the same reference numerals, and redundant description will be omitted.

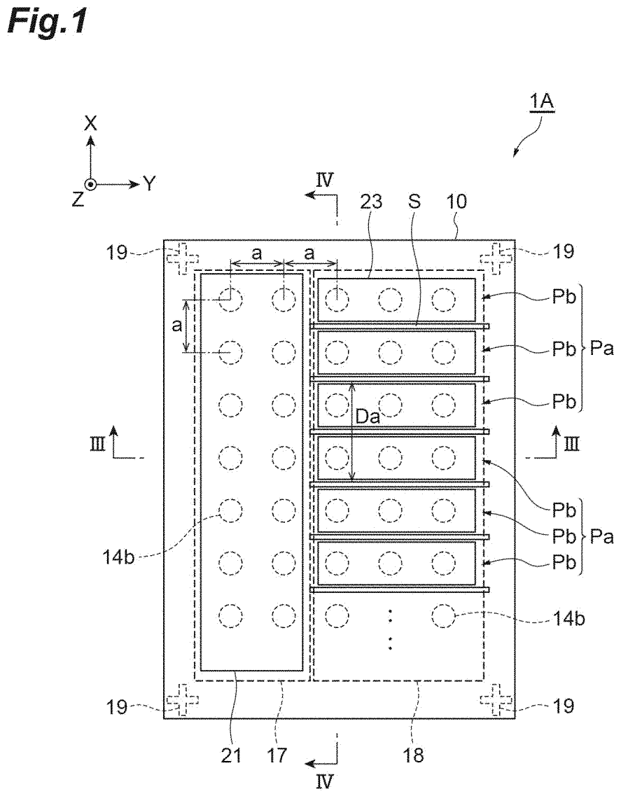

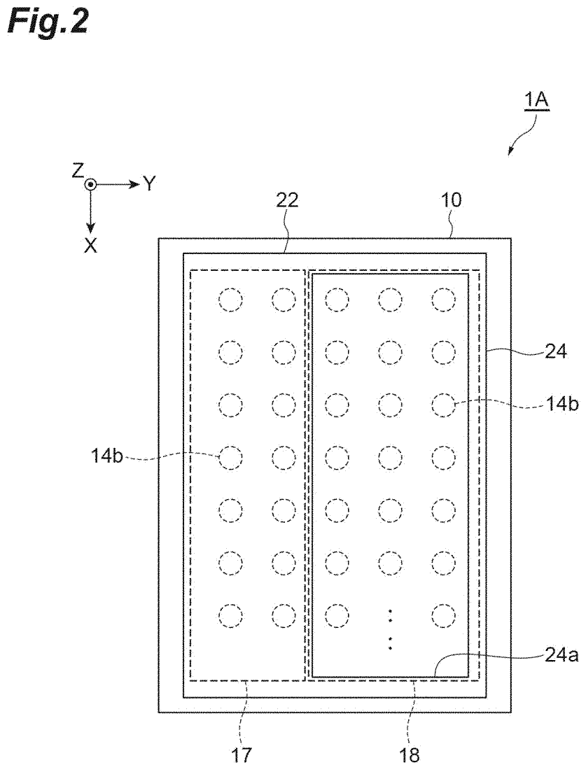

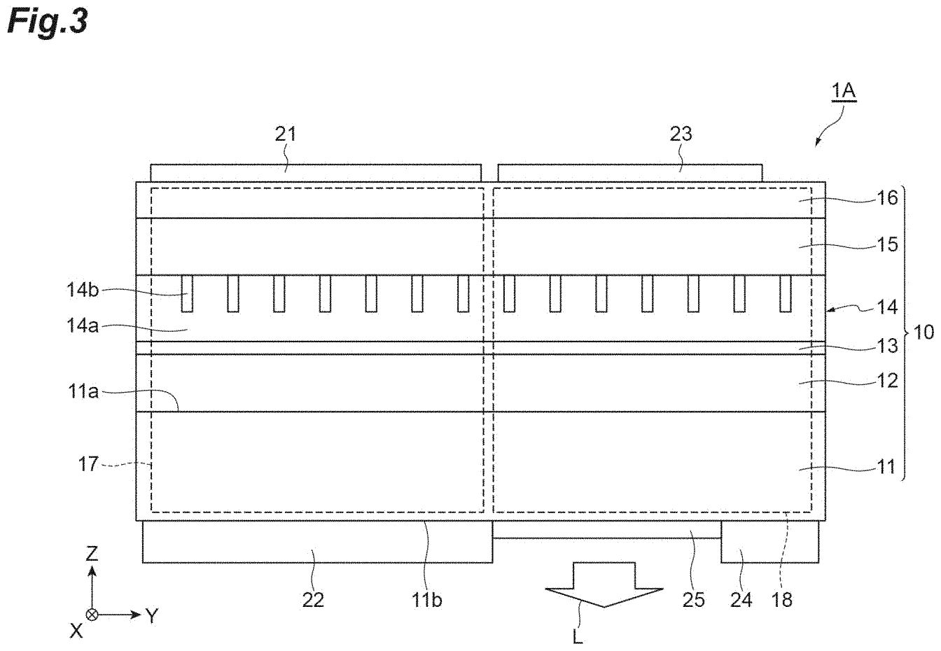

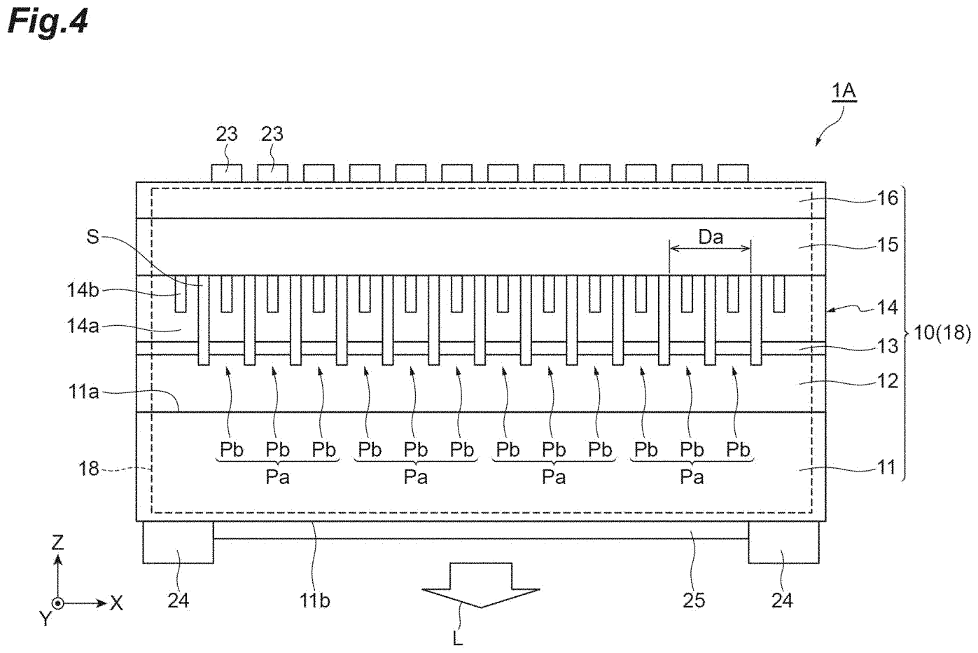

FIG. 1 is a plan view of a light source module 1A according to an embodiment of the present disclosure. FIG. 2 is a bottom view of the light source module 1A. FIG. 3 is a view schematically illustrating a cross section taken along line III-III of FIG. 1. FIG. 4 is a view schematically illustrating a cross section taken along line Iv-Iv of FIG. 1. In FIGS. 1 to 4, a common XYZ orthogonal coordinate system is illustrated. The light source module 1A includes a semiconductor stack portion 10, a first electrode 21, a second electrode 22, a plurality of third electrodes 23, a fourth electrode 24, and an antireflection film 25. The semiconductor stack portion 10 includes a semiconductor substrate 11 having a main surface 11a and a back surface 11b opposed to the main surface 11a, and a plurality of semiconductor layers stacked on the main surface 11a. A thickness direction of the semiconductor substrate 11 (that is, a normal direction of the main surface 11a) and the stacking direction of a plurality of the semiconductor layers coincide with a Z-direction. A plurality of the semiconductor layers of the semiconductor stack portion 10 include a first cladding layer 12, an active layer 13, a photonic crystal layer 14, a second cladding layer 15, and a contact layer 16.

The main surface 11a and the back surface 11b of the semiconductor substrate 11 are flat and parallel to each other. The semiconductor substrate 11 is used for epitaxially growing a plurality of the semiconductor layers of the semiconductor stack portion 10. In a case where a plurality of the semiconductor layers of the semiconductor stack portion 10 are GaAs-based semiconductor layers, the semiconductor substrate 11 is, for example, a GaAs substrate. In a case where a plurality of the semiconductor layers of the semiconductor stack portion 10 are InP-based semiconductor layers, the semiconductor substrate 11 is, for example, an InP substrate. In a case where a plurality of the semiconductor layers of the semiconductor stack portion 10 are GaN-based semiconductor layers, the semiconductor substrate 11 is, for example, a GaN substrate. A thickness of the semiconductor substrate 11 is, for example, in a range of 50 μm to 1000 μm. The semiconductor substrate 11 has p-type or n-type conductivity. A planar shape of the main surface 11a is, for example, a rectangular or square shape.

The first cladding layer 12 is a semiconductor layer formed on the main surface 11a of the semiconductor substrate 11 by epitaxial growth. The first cladding layer 12 has the same conductivity type as that of the semiconductor substrate 11. The semiconductor substrate 11 and the first cladding layer 12 constitute the first conductivity type semiconductor layer in the present disclosure. The first cladding layer 12 may be directly provided on the main surface 11a by epitaxial growth, or may be provided on the main surface 11a via a buffer layer provided between the main surface 11a and the first cladding layer 12. The active layer 13 is a semiconductor layer formed on the first cladding layer 12 by epitaxial growth. The active layer 13 generates light by receiving supply of a current. The photonic crystal layer 14 is a semiconductor layer formed on the active layer 13 by epitaxial growth. The second cladding layer 15 is a semiconductor layer formed on the photonic crystal layer 14 by epitaxial growth. The contact layer 16 is a semiconductor layer formed on the second cladding layer 15 by epitaxial growth. The second cladding layer 15 and the contact layer 16 have a conductivity type opposite to that of the first cladding layer 12. The second cladding layer 15 and the contact layer 16 constitute the second conductivity type semiconductor layer in the present disclosure.

A refractive index of the active layer 13 is greater than refractive indexes of the first cladding layer 12 and the second cladding layer 15, and a band gap of the active layer 13 is smaller than band gaps of the first cladding layer 12 and the second cladding layer 15. The photonic crystal layer 14 may be provided between the first cladding layer 12 and the active layer 13 or between the active layer 13 and the second cladding layer 15. Another semiconductor layer (for example, an optical confinement layer) may be further provided between the active layer 13 and photonic crystal layer 14 and the first cladding layer 12, between the active layer 13 and photonic crystal layer 14 and the second cladding layer 15, or both.

The photonic crystal layer 14 has a two-dimensional diffraction lattice. The photonic crystal layer 14 includes a base layer 14a and a plurality of modified refractive index regions 14b provided inside the base layer 14a. Refractive indexes of the modified refractive index regions 14b are different from the refractive index of the base layer 14a. The modified refractive index regions 14b are disposed at constant intervals in the X-direction and the Y-direction in the base layer 14a. Each of the modified refractive index regions 14b may be a hole, or may be configured by embedding a semiconductor having a refractive index different from that of the base layer 14a in the hole. The planar shape of each of the modified refractive index regions 14b may be various shapes such as a circular shape, a polygonal shape (triangle, quadrangle, and the like), and an elliptical shape.

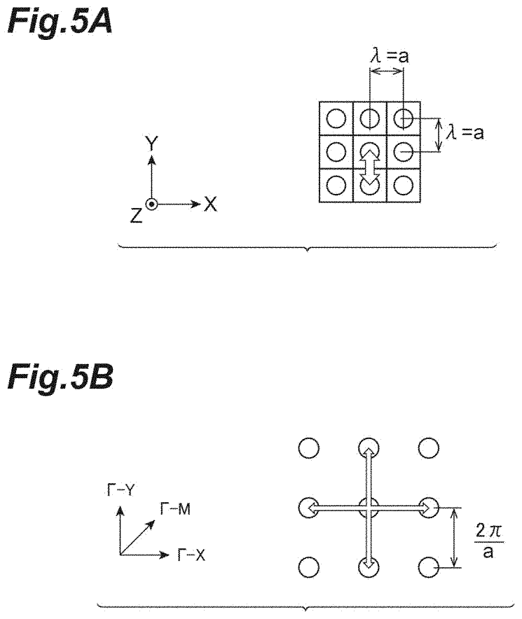

The modified refractive index regions 14b are disposed at intervals so as to satisfy a condition off-point oscillation with respect to the emission wavelength of the active layer 13. FIG. 5A is a diagram for explaining the Γ-point oscillation in the real space. FIG. 5B is a diagram for explaining the Γ-point oscillation in a reciprocal lattice space. The circles illustrated in FIGS. 5A and 5B represent the modified refractive index regions 14b.

FIG. 5A illustrates a case where the modified refractive index region 14b is located at an opening center of the lattice frame of the square lattice in the real space in which an XYZ three-dimensional orthogonal coordinate system is set. A lattice interval of the square lattice is a, and a gravity center interval of the modified refractive index regions 14b adjacent in an X-axis direction and a Y-axis direction is also a. The oscillation at the Γ point in the photonic crystal layer 14 occurs in a case where λ/n coincides with a, where the emission wavelength of the active layer 13 is λ and an effective refractive index of the photonic crystal layer 14 at the wavelength λ is n. FIG. 5B illustrates a reciprocal lattice of the lattice of FIG. 5A, and the interval between adjacent modified refractive index regions 14b in a longitudinal direction (Γ-Y) or a transverse direction (Γ-X) is 2π/a. This 2π/a coincides with 2nₑπ/λ, (nₑ is the effective refractive index of the photonic crystal layer 14). Note that in this example, the case where the modified refractive index region 14b is located at the opening center of the lattice frame of the square lattice has been described, but the modified refractive index region 14b may be located at the opening center of the lattice frame of another lattice (for example, a triangular lattice).

FIGS. 1 to 4 will be referred to again. As illustrated in FIG. 1, a cross-shaped mark 19 for positioning, which is used at the time of manufacturing the light source module 1A, is formed at an interface between the photonic crystal layer 14 and the second cladding layer 15. In one example, in a plan view, the marks 19 are formed near four corners of the light source module 1A except for a region where a phase synchronization portion 17 and an intensity modulation portion 18 to be described later are formed.

The semiconductor stack portion 10 includes the phase synchronization portion 17 and the intensity modulation portion 18. The phase synchronization portion 17 and the intensity modulation portion 18 are arranged in a Y-direction (first direction) which is one of the resonance directions of the photonic crystal layer 14. In one example, the phase synchronization portion 17 and the intensity modulation portion 18 are adjacent to each other in the Y-direction. Another portion may be interposed between the phase synchronization portion 17 and the intensity modulation portion 18. The planar shapes of the phase synchronization portion 17 and the intensity modulation portion 18 are, for example, rectangular or square. In one example, the phase synchronization portion 17 and the intensity modulation portion 18 have a pair of sides facing each other in the X-direction and a pair of sides facing each other in the Y-direction. One side of the phase synchronization portion 17 on the intensity modulation portion 18 side in the X-direction and one side of the intensity modulation portion 18 on the phase synchronization portion 17 side in the X-direction face each other while being separated from each other or coincide with each other. In the example illustrated in FIGS. 1 to 4, the shapes of the phase synchronization portion 17 and the intensity modulation portion 18 are rectangular shapes of which a longitudinal direction coincide with the X-direction and of which a short-length direction coincides with the Y-direction. The area of the planar shape of the phase synchronization portion 17 may be larger than the area of the planar shape of the intensity modulation portion 18, may be the same as the area of the planar shape of the intensity modulation portion 18, or may be smaller than the area of the planar shape of the intensity modulation portion 18.

As illustrated in FIGS. 1 and 4, the active layer 13 and the photonic crystal layer 14 of the intensity modulation portion 18 have M (M is an integer of two or more) pixels Pa. Although two pixels Pa are exemplarily illustrated in FIG. 1 and four pixels Pa are exemplarily illustrated in FIG. 4, the number M of pixels Pa is any number of two or more. The pixels Pa are disposed side by side in a direction intersecting the Y-direction (second direction, for example, X-direction). A planar shape of each pixel Pa is, for example, rectangular or square. That is, each pixel Pa has a pair of sides facing each other in the X-direction and a pair of sides facing each other in the Y-direction.

Each pixel Pa includes N₁ (N₁ is an integer of two or more) subpixels Pb arranged in the arrangement direction (for example, the X-direction) of the pixel Pa. FIGS. 1 and 4 exemplarily illustrate a case where the number N₁ of the pixels Pa is three, but the number N₁ may be two or the arbitrary number of four or more. A planar shape of each subpixel Pb is a rectangular shape of which a longitudinal direction coincides with the Y-direction and of which a short-length direction coincides with the arrangement direction of the subpixels Pb (for example, the X-direction). One side along the arrangement direction of the phase synchronization portion 17 and one side along the arrangement direction of each subpixel Pb face each other while being separated from each other or coincide with each other. Each subpixel Pb is directly optically coupled to the phase synchronization portion 17 without passing through the other subpixels Pb. In each pixel Pa, a length Da of a region including consecutive N₂ (N₂ is an integer of two or more and N₁ or less) subpixels Pb, which is defined in the arrangement direction (specifically, a distance between two slits S interposing the region), is smaller than an emission wavelength λ of the active layer 13 (that is, the wavelength of laser light beam L outputted from each pixel Pa). Here, the wavelength λ means a wavelength in the atmosphere. As an example, in a case where N₁=3 and N₂=2, the length of each pixel Pa in the arrangement direction is 1.5 times the length Da. In a case where at least two subpixels Pb that are not adjacent to each other in each pixel Pa (that are separated from each other with another subpixel Pb interposed therebetween) simultaneously output the laser light beam L, the length defined in the arrangement direction of the pixels Pa may be smaller than the emission wavelength λ.

The semiconductor stack portion 10 further includes a plurality of the slits S. Each of the slits S is a groove formed in the semiconductor stack portion 10 and is a gap. The slits S extend in the Y-direction and in the Z-direction which is a depth direction, and the subpixels Pb and the slits S are alternately disposed one by one in the arrangement direction of the subpixels Pb (for example, the X-direction). Therefore, the slit S is located between the subpixels Pb adjacent to each other. Note that the slit S may not be a gap, and may be filled with, for example, a material having a higher resistance and a higher refractive index than the active layer 13 and the photonic crystal layer 14. The intensity modulation portion 18 is optically and electrically divided into a plurality of the subpixels Pb by the slit S. A width of each slit S defined in the arrangement direction of the subpixels Pb is less than λ/N₁, and an interval between the adjacent slits S (that is, a width of each subpixel Pb in the arrangement direction) is less than λ/N₁.

The first electrode 21 and the second electrode 22 are metal electrodes provided in the phase synchronization portion 17. The first electrode 21 is electrically connected to the contact layer 16 of the phase synchronization portion 17. In the present embodiment, the first electrode 21 is an ohmic electrode in contact with a surface of the contact layer 16 of the phase synchronization portion 17, and covers the entire surface of the contact layer 16 of the phase synchronization portion 17. The second electrode 22 is electrically connected to the semiconductor substrate 11 of the phase synchronization portion 17. In the present embodiment, the second electrode 22 is an ohmic electrode in contact with the back surface 11b of the semiconductor substrate 11 of the phase synchronization portion 17, and covers the entire back surface 11b of the semiconductor substrate 11 of the phase synchronization portion 17. Note that the present invention is not limited to this example, and the first electrode 21 may cover only a part of the surface of the contact layer 16 of the phase synchronization portion 17, and the second electrode 22 may cover only a part of the back surface 11b of the semiconductor substrate 11 of the phase synchronization portion 17. The second electrode 22 may be in ohmic contact with the first cladding layer 12 instead of the semiconductor substrate 11.

The third electrode 23 and the fourth electrode 24 are metal electrodes provided in the intensity modulation portion 18. The third electrode 23 is electrically connected to the contact layer 16 of the intensity modulation portion 18. In one example, the third electrode 23 is an ohmic electrode in contact with the surface of the contact layer 16 of the intensity modulation portion 18. The third electrode 23 is provided in one-to-one correspondence with each subpixel Pb. That is, M×N₁ third electrodes 23 are provided on the contact layer 16 in correspondence with the respective subpixels Pb. A planar shape of each of the third electrodes 23 is similar to the planar shape of each subpixel Pb, and is, for example, a rectangular shape of which a longitudinal direction thereof coincides with the Y-direction.

The fourth electrode 24 is electrically connected to the semiconductor substrate 11 of the intensity modulation portion 18. In one example, the fourth electrode 24 is an ohmic electrode in contact with the back surface 11b of the semiconductor substrate 11 of the intensity modulation portion 18. The fourth electrode 24 has an opening 24a through which the laser light beam L outputted from the intensity modulation portion 18 passes. A planar shape of the fourth electrode 24 is a rectangular or square frame shape surrounding the opening 24a. The laser light beam L is outputted from each pixel Pa in a direction intersecting both the X-direction and the Y-direction (for example, the Z-direction).

The antireflection film 25 is provided inside the opening 24a of the fourth electrode 24 on the back surface 11b, and prevents the laser light beam L to be outputted from the semiconductor substrate 11 from being reflected by the back surface lib. The antireflection film 25 is comprised of an inorganic material such as a silicon compound.

The conductivity type of the semiconductor substrate 11 and the first cladding layer 12 is, for example, n-type. The conductivity type of the second cladding layer 15 and the contact layer 16 is, for example, p-type. A specific example of the light source module 1A will be described below.

### SPECIFIC EXAMPLE

The semiconductor substrate 11: n-type GaAs substrate (thickness of about 150 μm)

The first cladding layer 12: n-type AlGaAs (refractive index: 3.39, thickness: 0.5 μm or greater and 5 μm or less)

The active layer 13: InGaAs/AlGaAs multiple quantum well structure (thickness of InGaAs layer: 10 nm, thickness of AlGaAs layer: 10 nm, and 3 periods)

The second cladding layer 15: p-type AlGaAs (refractive index: 3.39, thickness: 0.5 μm or greater and 5 μm or less)

The contact layer 16: p-type GaAs (thickness 0.05 μm or greater and 1 μm or less)

The base layer 14a: i-type GaAs (thickness 0.1 μm or greater and 2 μm or less)

The modified refractive index region 14b: pores, arrangement period: 282 nm

The first electrode 21 and the third electrode 23: Cr/Au or Ti/Au

An arrangement pitch of the third electrode 23 (arrangement pitch of subpixels Pb): 564 nm

The total number of the third electrodes 23 (the total number M×N₁ of subpixels Pb): 351

The total number M of pixels Pa: 117

The second electrode 22 and the fourth electrode 24: GeAu/Au

The antireflection film 25: for example, a silicon compound film of SiN, SiO₂, or the like (thickness of 0.1 μm or greater and 0.5 μm or less)

Widths of the phase synchronization portion 17 and the intensity modulation portion 18 in the X-direction: 200 μm

A width of the phase synchronization portion 17 in the Y-direction: 150 μm

A width of the intensity modulation portion 18 in the Y-direction: 50 μm

A chip size: 700 μm on one side

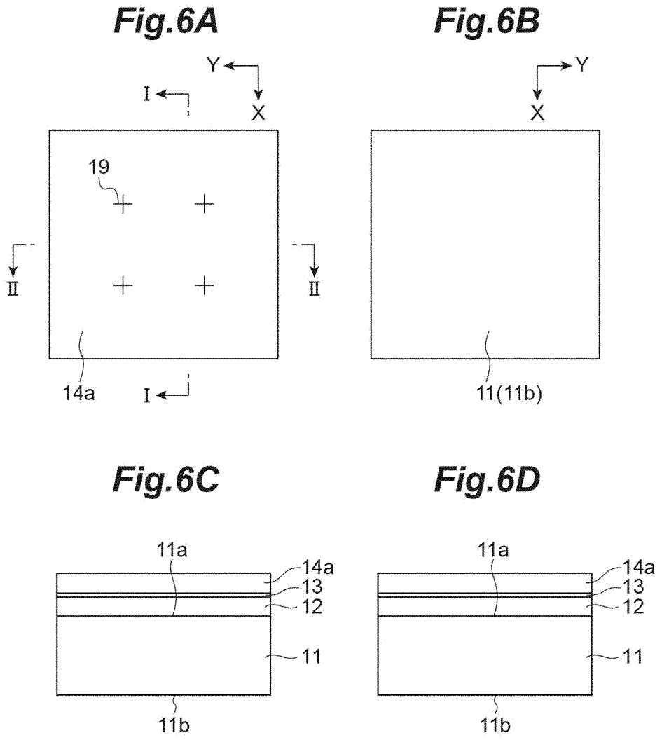

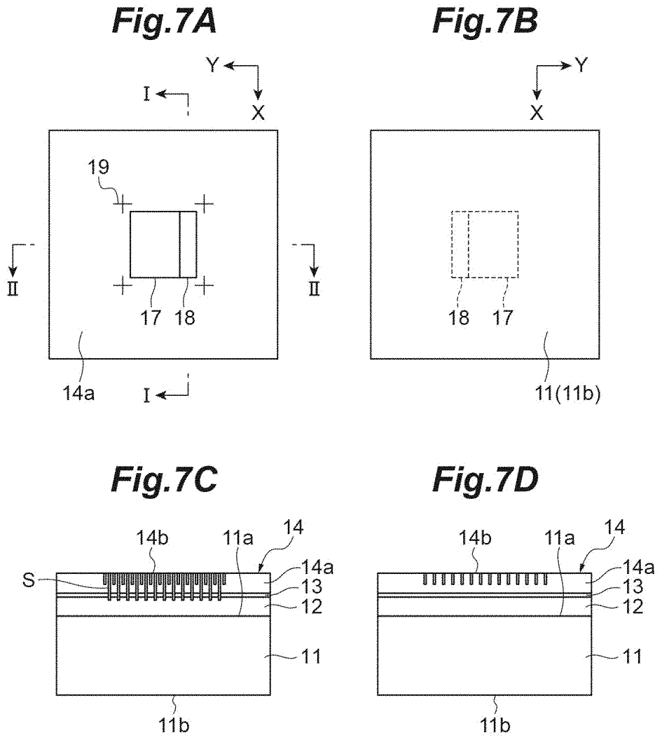

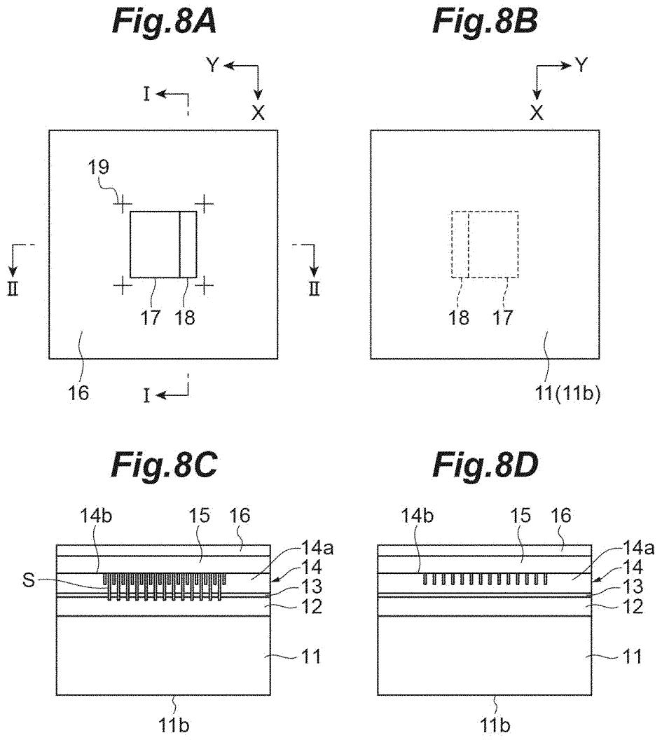

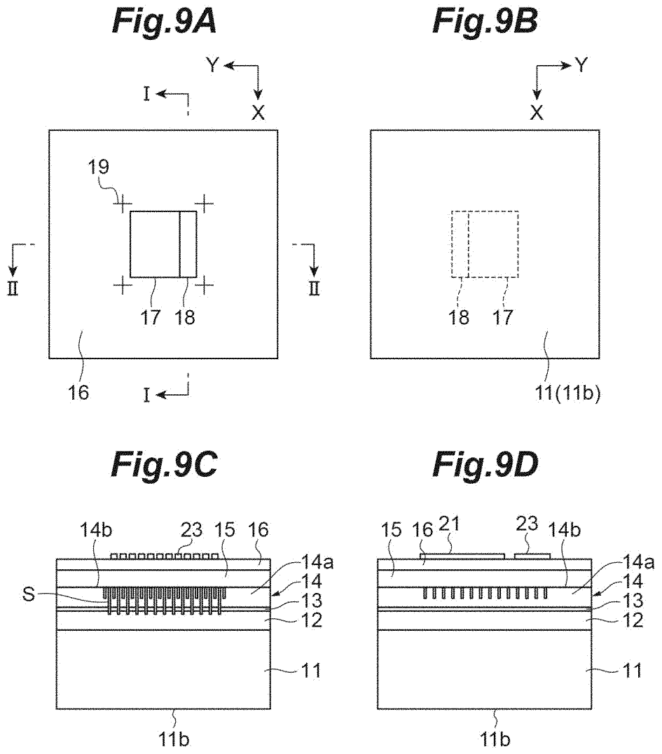

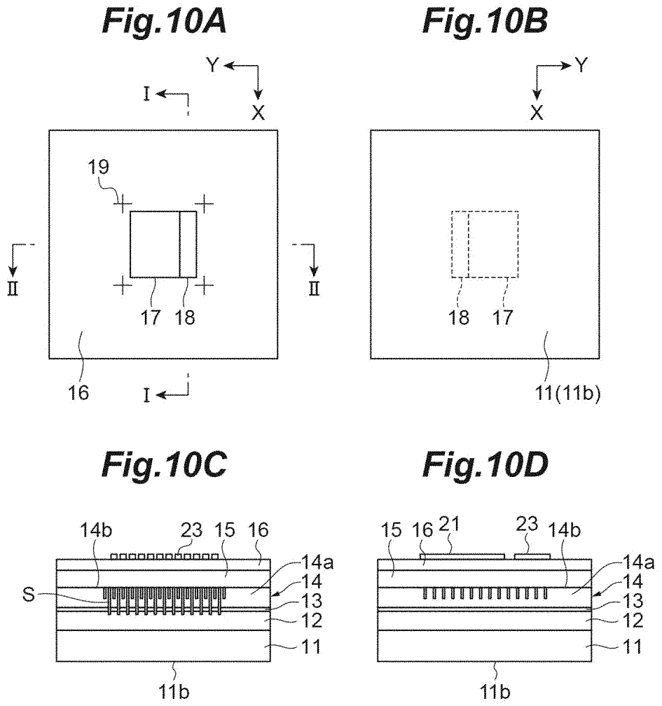

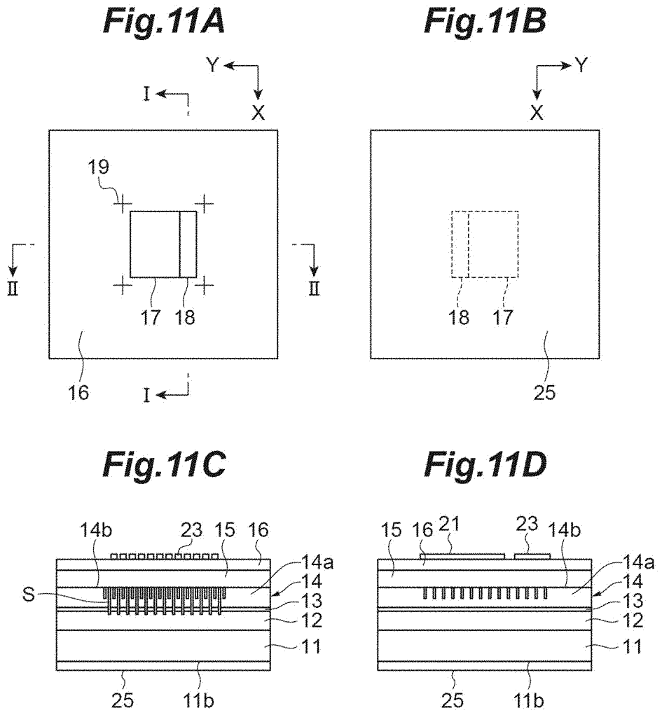

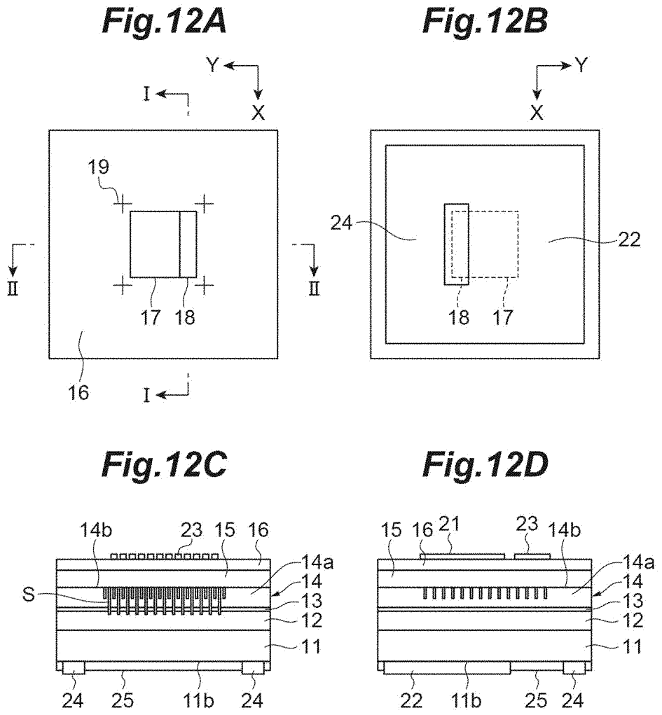

Here, an example of a method for manufacturing the light source module 1A will be described with reference to FIGS. 6A to 6D, FIGS. 7A to 7D, FIGS. 8A to 8D, FIGS. 9A to 9D, FIGS. 10A to 10D, FIGS. 11A to 11D, and FIGS. 12A to 12D. Note that FIG. 6A is a plan view, FIG. 6B is a bottom view, FIG. 6C is a schematic view of a cross section taken along line I-I of FIG. 6A, and FIG. 6D is a schematic view of a cross section taken along line II-II of FIG. 6A. FIG. 7A is a plan view, FIG. 7B is a bottom view, FIG. 7C is a schematic view of a cross section taken along line I-I of FIG. 7A, and FIG. 7D is a schematic view of a cross section taken along line II-II of FIG. 7A. FIG. 8A is a plan view, FIG. 8B is a bottom view, FIG. 8C is a schematic view of a cross section taken along line I-I of FIG. 8A, and FIG. 8D is a schematic view of a cross section taken along line II-II of FIG. 8A. FIG. 9A is a plan view, FIG. 9B is a bottom view, FIG. 9C is a schematic view of a cross section taken along line I-I of FIG. 9A, and FIG. 9D is a schematic view of a cross section taken along line II-II of FIG. 9A. FIG. 10A is a plan view, FIG. 10B is a bottom view, FIG. 10C is a schematic view of a cross section taken along line I-I of FIG. 10A, and FIG. 10D is a schematic view of a cross section taken along line II-II of FIG. 10A. FIG. 11A is a plan view, FIG. 11B is a bottom view, FIG. 11C is a schematic view of a cross section taken along line I-I of FIG. 11A, and FIG. 11D is a schematic view of a cross section taken along line II-II of FIG. 11A. FIG. 12A is a plan view, FIG. 12B is a bottom view, FIG. 12C is a schematic view of a cross section taken along line I-I of FIG. 12A, and FIG. 12D is a schematic view of a cross section taken along line II-II of FIG. 12A.

First, as illustrated in FIGS. 6A to 6D, epitaxial growth is performed to form the first cladding layer 12, the active layer 13, and the base layer 14a of the photonic crystal layer 14 in this order on the main surface 11a of the semiconductor substrate 11 by using a metal organic chemical vapor deposition (MOCVD) method. The positioning mark 19 is formed on the surface of the base layer 14a. The mark 19 is formed by, for example, electron beam lithography and dry etching.

Next, by the way, as illustrated in FIGS. 7A to 7D, a plurality of the modified refractive index regions 14b and a plurality of the slits S are formed. Specifically, first, a SiN film is formed on the base layer 14a, and then a resist mask is formed on the SiN film by using an electron beam lithography technique with the mark 19 as a reference. This resist mask has an opening corresponding to the position and shape of the modified refractive index region 14b satisfying the condition of the Γ-point oscillation on a portion constituting a part of the phase synchronization portion 17 and a portion constituting a part of the intensity modulation portion 18 in the base layer 14a. Furthermore, the resist mask has an opening corresponding to the position and shape of the slit S on a portion consisting a part of the intensity modulation portion 18 in the base layer 14a. Dry etching (for example, reactive ion etching) is performed on the SiN film via the resist mask, and thus an etching mask comprised of SiN is formed. The dry etching (for example, inductively-coupled plasma etching) is performed on the base layer 14a and the active layer 13 via the etching mask. According to this, recess portions as a plurality of the modified refractive index regions 14b satisfying the condition of the Γ-point oscillation are formed to a depth not penetrating the base layer 14a. At the same time, the recess portions as a plurality of the slits S are formed to a depth reaching the first cladding layer 12 through the photonic crystal layer 14 and the active layer 13. By appropriately setting a ratio of a lateral width of the slit S and a diameter of the modified refractive index region 14b, an etching rate of the slit S can be made greater than an etching rate of the modified refractive index region 14b, and thus the slit S is formed deeper than the modified refractive index region 14b even in the same etching time. Thereafter, the resist mask and the etching mask are removed. In this manner, the photonic crystal layer 14 having the base layer 14a and a plurality of the modified refractive index regions 14b, and a plurality of the slits S are formed. Note that the modified refractive index region 14b may be formed by filling the recess portion of the base layer 14a with a semiconductor having a refractive index different from that of the base layer 14a. Furthermore, the slit S may be filled with a high resistor having a refractive index greater than that of the base layer 14a.

Alternatively, a region having a high refractive index and a high resistance may be formed by performing ion implantation (for example, oxide ion implantation) via the etching mask instead of forming the slit S.

Subsequently, as illustrated in FIGS. 8A to 8D, the epitaxial growth is performed to form the second cladding layer 15 and the contact layer 16 in this order on the photonic crystal layer 14 by using the MOCVD method. Through the above-described steps, the semiconductor stack portion 10 including the phase synchronization portion 17 and the intensity modulation portion 18 is formed.

Subsequently, as illustrated in FIGS. 9A to 9D, the first electrode 21 is formed on the contact layer 16 of the phase synchronization portion 17, and a plurality of the third electrodes 23 are formed on the contact layer 16 of the intensity modulation portion 18. Specifically, first, a resist mask having openings corresponding to the first electrode 21 and the third electrode 23 is formed on the contact layer 16 by using an electron beam lithography technique with the mark 19 as a reference. After materials of the first electrode 21 and the third electrode 23 are deposited by a vacuum deposition method, the deposited portions other than the first electrode 21 and the third electrode 23 are removed together with the resist mask by a lift-off method.

Subsequently, as illustrated in FIGS. 10A to 10D, the semiconductor substrate 11 is thinned by polishing the back surface 11b of the semiconductor substrate 11. Moreover, the back surface 11b is mirror-polished. Due to this polishing and mirror-polishing, an absorption amount of the laser light beam L in the semiconductor substrate 11 is reduced, and furthermore, by making the back surface 11b from which the laser light beam L is outputted a smooth surface, extraction efficiency of the laser light beam L is increased.

Subsequently, as illustrated in FIGS. 11A to 11D, the antireflection film 25 is formed on the entire back surface 11b of the semiconductor substrate 11 by using a plasma CVD method. A resist mask having openings corresponding to the second electrode 22 and the fourth electrode 24 is formed on the antireflection film 25 by using a photolithography technique with the mark 19 as a reference. By performing wet etching or dry etching via the resist mask, openings corresponding to the second electrode 22 and the fourth electrode 24 are formed in the antireflection film 25. In a case where the antireflection film 25 is a silicon compound film, for example, buffered hydrofluoric acid can be used as an etchant of the wet etching. Furthermore, as etching gas for dry etching, for example, CF₄ gas can be used.

Subsequently, as illustrated in FIGS. 12A to 12D, the second electrode 22 is formed on the back surface 11b of a portion of the semiconductor substrate 11 included in the phase synchronization portion 17, and the fourth electrode 24 is formed on the back surface 11b of a portion of the semiconductor substrate 11 included in the intensity modulation portion 18. Specifically, first, a resist mask having openings corresponding to the second electrode 22 and the fourth electrode 24 is formed on the antireflection film 25 by using a photolithography technique with the mark 19 as a reference. After materials of the second electrode 22 and the fourth electrode 24 are deposited by a vacuum deposition method, the deposited portions other than the second electrode 22 and the fourth electrode 24 are removed together with the resist mask by a lift-off method. Finally, annealing is performed to alloy the first electrode 21, the second electrode 22, the third electrode 23, and the fourth electrode 24. The light source module 1A according to the present embodiment is manufactured through the above-described steps.

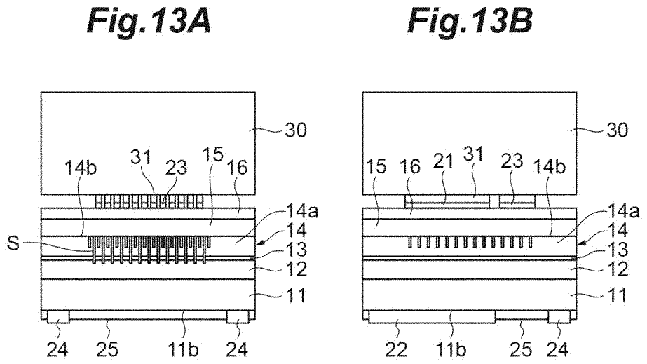

Thereafter, as illustrated in FIGS. 13A and 13B, the light source module 1A is flip-chip mounted on a control circuit board 30 as necessary. That is, the first electrode 21 and the third electrode 23 of the light source module 1A, and a wiring pattern provided on the control circuit board 30 corresponding to the first electrode 21 and the third electrode 23 are bonded to each other by a conductive bonding material 31 such as solder. FIG. 13A is a schematic view corresponding to the I-I cross section illustrated in FIGS. 6A, 7A, 8A, 9A, 10A, 11A, and 12A, and FIG. 13B is a schematic view corresponding to the II-II cross section illustrated in FIGS. 6A, 7A, 8A, 9A, 10A, 11A, and 12A. The second electrode 22 and the fourth electrode 24 are connected to the control circuit board 30 by wire bonding.

As described above, operational effects obtained by the light source module 1A according to the present embodiment will be described. When a bias current is supplied between the first electrode 21 and the second electrode 22, and between the third electrode 23 and the fourth electrode 24, carriers are collected between the first cladding layer 12 and the second cladding layer 15 in each of the phase synchronization portion 17 and the intensity modulation portion 18, and light is efficiently generated in the active layer 13. The light outputted from the active layer 13 enters the photonic crystal layer 14, and resonates in the X-direction and in the Y-direction, which are perpendicular to the thickness direction in the photonic crystal layer 14. This light becomes a phase-aligned coherent laser light beam in the photonic crystal layer 14 of the phase synchronization portion 17.

Since the photonic crystal layer 14 of the intensity modulation portion 18 is arranged in the Y-direction with respect to the photonic crystal layer 14 of the phase synchronization portion 17, a phase of the laser light beam in the photonic crystal layer 14 of each subpixel Pb coincides with a phase of the laser light beam in the photonic crystal layer 14 of the phase synchronization portion 17. As a result, the phases of the laser light beams in the photonic crystal layer 14 are aligned between the subpixels Pb. Since the photonic crystal layer 14 of the present embodiment causes Γ-point oscillation, the phase-aligned laser light beam L is outputted from each subpixel Pb of the intensity modulation portion 18 in a direction intersecting both the X-direction and the Y-direction (typically, the Z-direction). A part of the laser light beam L directly reaches the semiconductor substrate 11 from the photonic crystal layer 14. Furthermore, the rest of the laser light beam L reaches the third electrode 23 from the photonic crystal layer 14, is reflected by the third electrode 23, and then reaches the semiconductor substrate 11. The laser light beam L passes through the semiconductor substrate 11, and exits from the back surface 11b of semiconductor substrate 11 to the outside of the light source module 1A through the opening 24a of the fourth electrode 24.

The third electrode 23 is provided in correspondence with each subpixel Pb. Therefore, the magnitude of the bias current supplied to the intensity modulation portion 18 can be individually adjusted for each subpixel Pb. That is, light intensity of the laser light beam L outputted from the intensity modulation portion 18 can be adjusted individually (independently) for each subpixel Pb. Furthermore, in each pixel Pa, the length Da of the region including consecutive N₂ subpixels Pb in the arrangement direction (X-direction) is smaller than the emission wavelength λ of the active layer 13, that is, the wavelength of the laser light beam L.

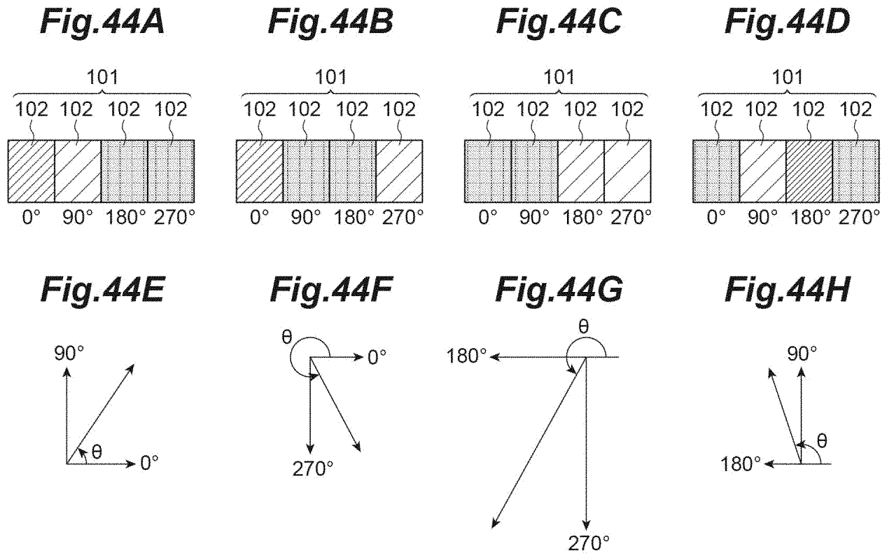

Here, FIGS. 44A to 44H are diagrams for explaining a technique described in Non-Patent Document 1. FIGS. 44A to 44D illustrate a pixel 101 including four subpixels 102 arranged in one direction, and the reflectance of each subpixel 102 is expressed with the density of hatching. Here, the coarser the hatching, the greater the reflectance (that is, light intensity of the reflected light is greater). In this case, four subpixels 102 can be regarded as one pixel having a single phase equivalently by collecting four subpixels 102. In a case where the phases of the reflected light beams from four subpixels 102 are aligned with each other, the phase of the light outputted from the pixel 101 is determined in accordance with the intensity distribution of four subpixels 102. For example, four subpixels 102 correspond to phases of 0°, 90°, 180°, and 270° from the left side, respectively. In this case, as illustrated in FIG. 44A, the reflected light beams are not outputted from two subpixels 102 respectively corresponding to 180° and 270°, and by controlling an intensity ratio of the reflected light beams of two subpixels 102 respectively corresponding to 0° and 90°, as illustrated in FIG. 44E, a phase θ of the light outputted from the pixel 101 can be controlled to have any value of from 0° to 90°. Furthermore, as illustrated in FIG. 44B, the reflected light beams are not outputted from two subpixels 102 respectively corresponding to 90° and 180°, and by controlling the intensity ratio of the reflected light beams of two subpixels 102 respectively corresponding to 0° and 270°, as illustrated in FIG. 44F, the phase θ of the light outputted from the pixel 101 can be controlled to have any value of from 270° to 0° (360°). Furthermore, as illustrated in FIG. 44C, the reflected light beams are not outputted from two subpixels 102 respectively corresponding to 0° and 90°, and by controlling the intensity ratio of the reflected light beams of two subpixels 102 respectively corresponding to 180° and 270°, as illustrated in FIG. 44G, the phase θ of the light outputted from the pixel 101 can be controlled to have any value of 180° to 270°. Furthermore, as illustrated in FIG. 44D, the reflected light beams are not outputted from two subpixels 102 respectively corresponding to 0° and 270°, and by controlling the intensity ratio of the reflected light beams of two subpixels 102 respectively corresponding to 90° and 180°, as illustrated in FIG. 44H, the phase θ of the light outputted from the pixel 101 can be controlled to have any value of from 90° to 180°.

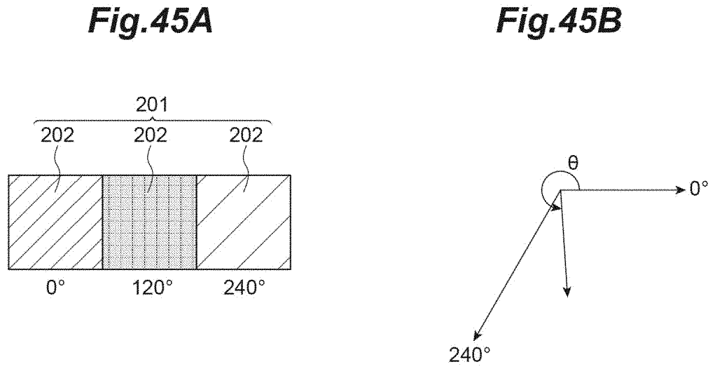

FIGS. 45A and 45B are diagrams for explaining a technique described in Non-Patent Document 2. FIG. 45A illustrates a pixel 201 including three subpixels 202 arranged in one direction, and the reflectance of each subpixel 202 is expressed with the density of hatching. In this case, three subpixels 202 can be regarded as one pixel having a single phase equivalently by collecting three subpixels 202. Non-Patent Document 2 describes that in a case where the phases of the reflected light beams from three subpixels 202 are aligned with each other, the phase of the light outputted from the pixel 201 is determined in accordance with the intensity distribution of three subpixels 202. For example, three subpixels 202 correspond to phases of 0°, 120°, and 240° from the left side, respectively. In this case, for example, as illustrated in FIG. 45B, the reflected light is not outputted from the subpixel 202 corresponding to 120°, and by controlling the intensity ratio of the reflected light beams of two subpixels 202 respectively corresponding to 0° and 240°, the phase θ of the light outputted from the pixel 201 can be controlled to have any value of from 240° to 0° (360°). Note that the intensity of one of three subpixels 202 is always zero.

However, in the methods illustrated in FIGS. 44A to 44H, and FIGS. 45A and 45B, the light reflectance of each of the subpixels 102 and 202 is an uncontrollable fixed value. Therefore, the output phase of each of the pixels 101 and 201 cannot be dynamically controlled. On the other hand, the light source module 1A of the present embodiment can independently control the intensity of the laser light beams L outputted from the M×N₁ subpixels Pb included in each pixel Pa for each subpixel Pb. Since the phases of the laser light beams L are aligned with each other between N₁ subpixels Pb, the phase of the laser light beam L outputted from each pixel Pa is determined in accordance with the intensity distribution in the pixel Pa realized by the N₁ subpixels Pb. Therefore, in the light source module 1A of the present embodiment, it is possible to dynamically control the phase distribution of the laser light beam L. For example, in a case where N₁ is three or more, the phase distribution of the light can be dynamically controlled in a range of 0° to

Note that as described above, even in a case where each pixel Pa includes three or more subpixels Pb, the number of subpixels Pb that simultaneously output the light is limited to two. When a length of a region including two subpixels Pb in the arrangement direction is smaller than the emission wavelength λ of the active layer 13, two subpixels Pb can be regarded as pixels including a single light emission point equivalently. Therefore, when the range of the phase distribution that can be dynamically controlled is less than 360°, the number of subpixels Pb that simultaneously output the light is limited to consecutive N₂ (N₂ is an integer of two or more and N₁ or less), and the length Da of a region including the consecutive N₂ subpixels Pb in the arrangement direction may be set to be less than the emission wavelength λ of the active layer 13. Note that as described above, in a case where both the number N₁ and the number N₂ are three or more, a spatial phase in the X-direction of the laser light beam L outputted from each pixel Pa can be dynamically controlled in a range of 0° to 360°.

As described above, in the light source module 1A of the present embodiment, it is possible to dynamically control the phase distribution of the laser light beam L.

As in the present embodiment, the first electrode 21 may be in contact with the contact layer 16 and cover the entire surface of the contact layer 16 of the phase synchronization portion 17, and the second electrode 22 may be in contact with the semiconductor substrate 11 and cover the entire surface of the semiconductor substrate 11 of the phase synchronization portion 17. In this case, the laser light beam outputted from the phase synchronization portion 17 in the stacking direction (Z-direction) can is shielded by the first electrode 21 and the second electrode 22. The photonic crystal layer 14 of the phase synchronization portion 17 causes Γ-point oscillation, and thus such shielding by the first electrode 21 and the second electrode 22 is effective.

As in the present embodiment, the fourth electrode 24 may have a frame shape that is in contact with the semiconductor substrate 11 and surrounds the opening 24a through which the laser light beam L passes. In this case, while a sufficient bias current is supplied to the active layer 13 of the intensity modulation portion 18, the laser light beam L can be outputted through the opening 24a from the intensity modulation portion 18 in a direction intersecting both the X-direction and the Y-direction.

As in the present embodiment, the semiconductor stack portion 10 may have the slit S. A plurality of the subpixels Pb and the slits S may have a plurality of slits S alternately arranged one by one in the arrangement direction of the subpixels Pb. In this case, the intensity modulation portion 18 can be divided into a plurality of the subpixels Pb with a simple configuration.

As described above, in the present embodiment, the third electrode 23 corresponding to each subpixel Pb is in contact with the contact layer 16, and the frame-shaped fourth electrode 24 having the opening 24a is in contact with the back surface 11b of the semiconductor substrate 11. In the present embodiment or each modification example to be described later, the third electrode corresponding to each subpixel Pb may be provided on the back surface 11b of the semiconductor substrate 11 (or the first cladding layer 12), and the frame-shaped fourth electrode having an opening may be provided on the contact layer 16. That is, the third electrode provided corresponding to each subpixel Pb is electrically connected to one portion (semiconductor layer) of the portion of the first conductivity type semiconductor layer and the portion of the second conductivity type semiconductor layer which constitute a part of the intensity modulation portion 18, and the fourth electrode is electrically connected to the other portion (semiconductor layer) of the portion of the first conductivity type semiconductor layer and the portion of the second conductivity type semiconductor layer which constitute a part of the intensity modulation portion. According to this, it is possible to achieve the same operational effects as those of the present embodiment.

Furthermore, an arrangement pitch (center interval) of the third electrodes 23 defined in the arrangement direction of the subpixels Pb may be an integer multiple of a lattice interval a. In this case, the light intensity of the laser light beam L outputted from each subpixel Pb is brought close to a uniform state.

### First Modification Example

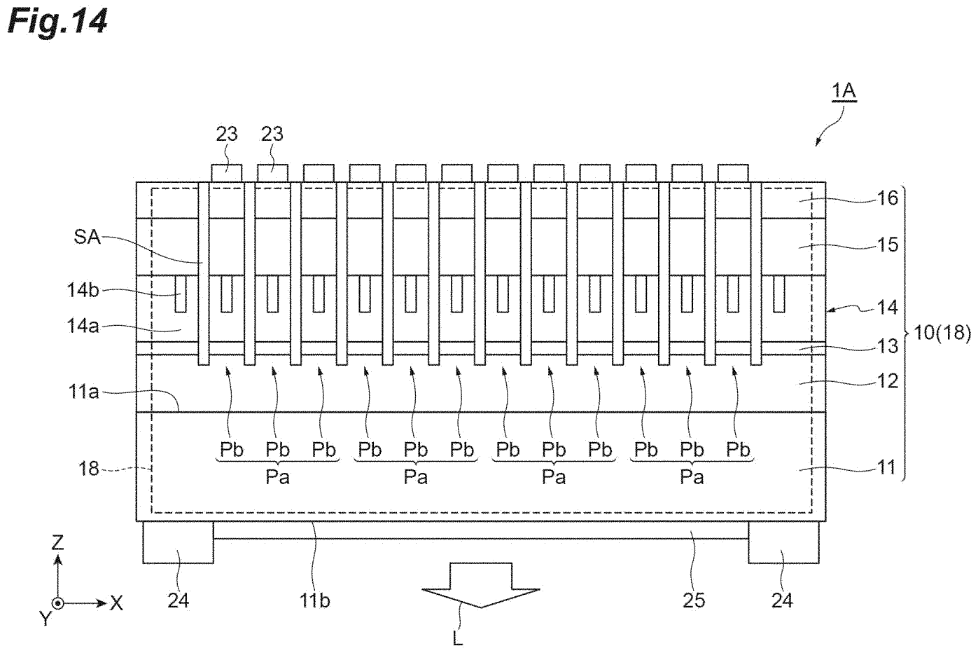

FIG. 14 is a view schematically illustrating a cross section of the light source module as the first modification example of the above-described embodiment, and illustrates a cross section corresponding to the Iv-Iv cross section illustrated in FIG. 1. This light source module is different from that of the above-described embodiment in the shape of the slit. The slit S of the above-described embodiment is formed inside the semiconductor stack portion 10 to divide the active layer 13 and the photonic crystal layer 14 (see FIG. 4), but a slit SA of the present modification example is formed from the surface to the inside of the semiconductor stack portion 10 to divide the second cladding layer 15 and the contact layer 16 in addition to the active layer 13 and the photonic crystal layer 14. That is, each subpixel Pb of the present modification example is formed by the active layer 13, the photonic crystal layer 14, the second cladding layer 15, and contact layer 16. Note that another aspect of the slit SA is similar to the aspect of the slit S of the above-described embodiment.

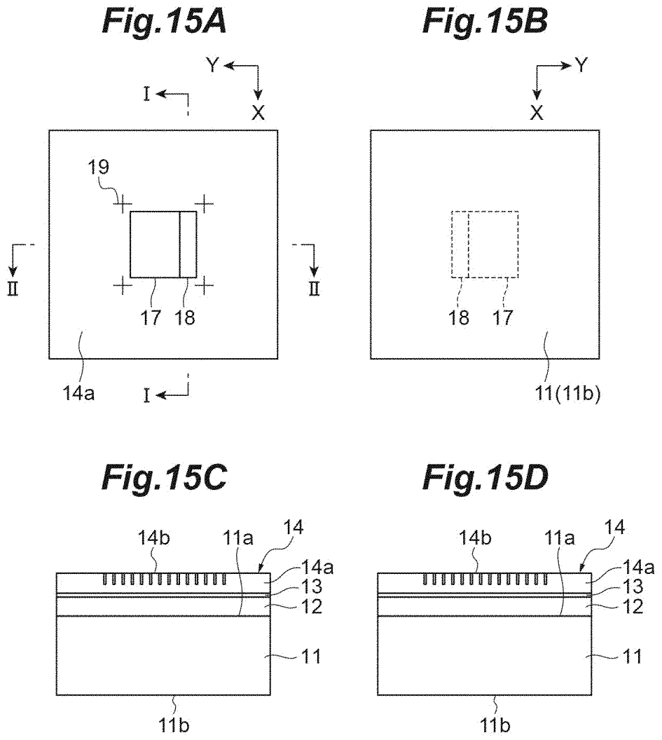

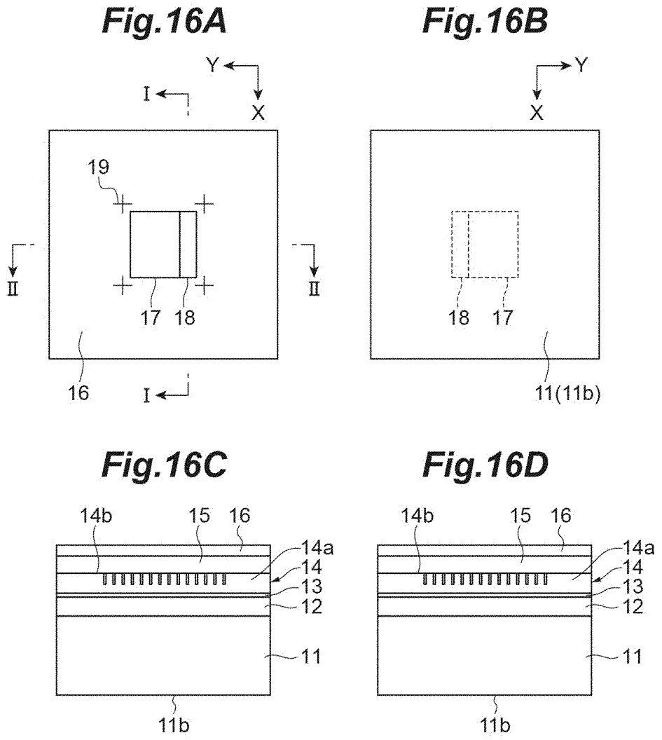

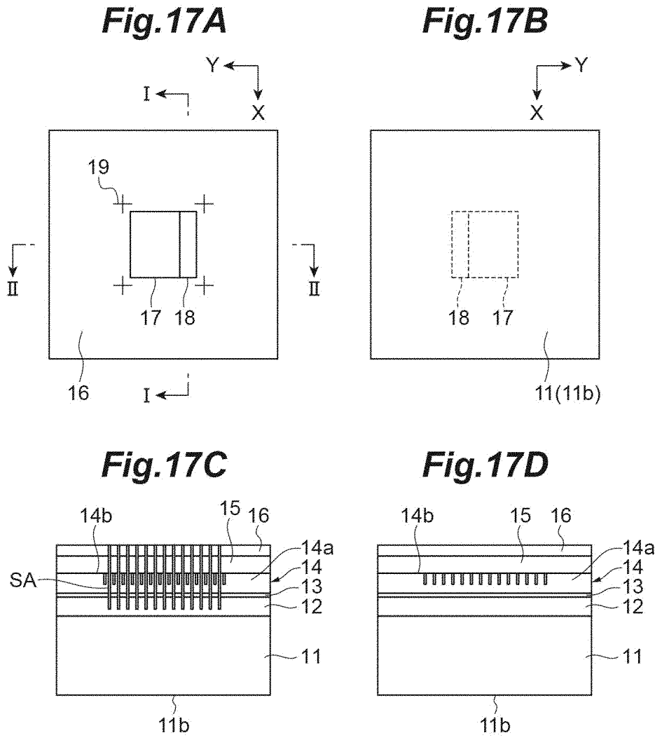

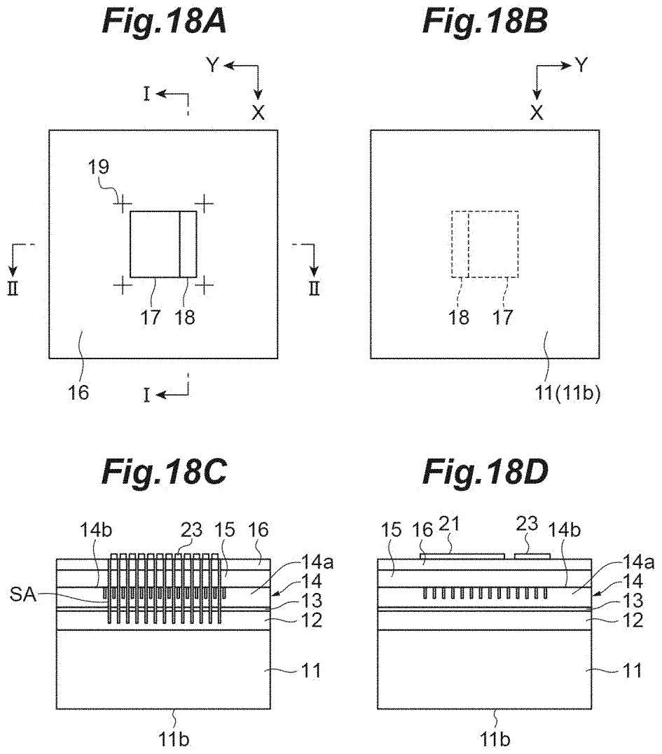

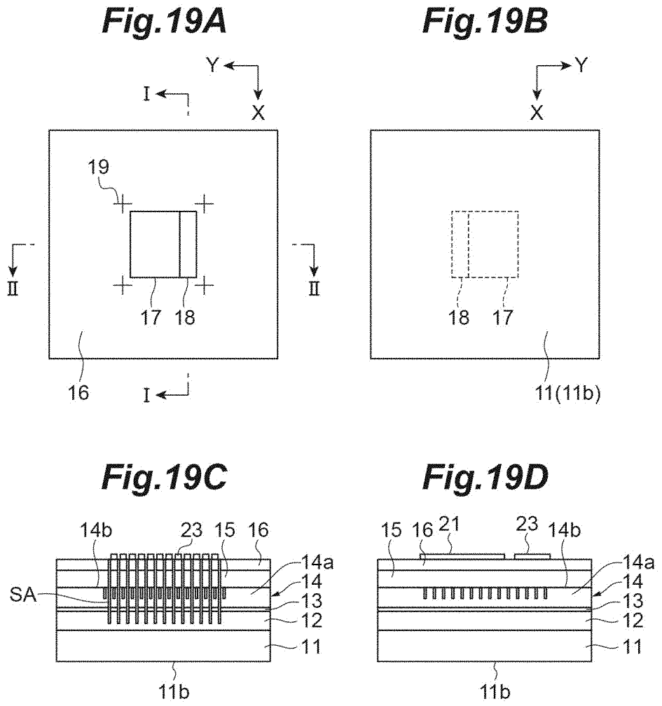

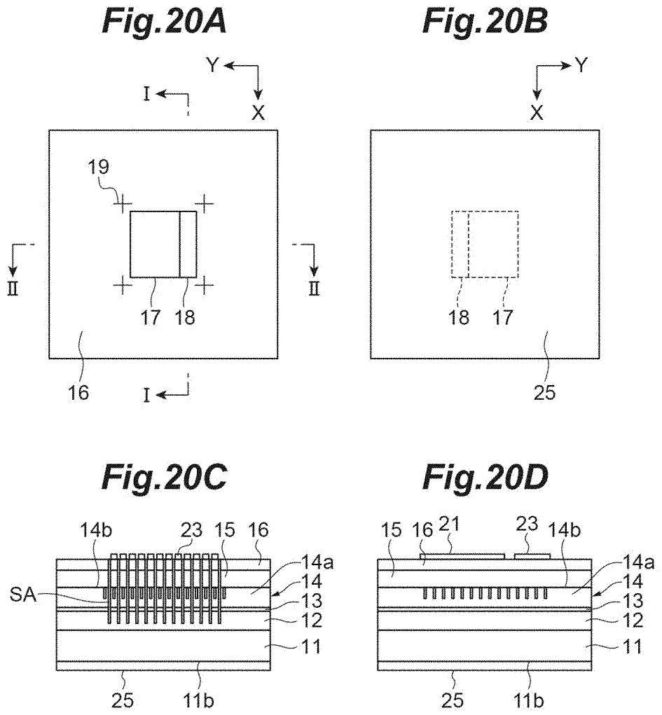

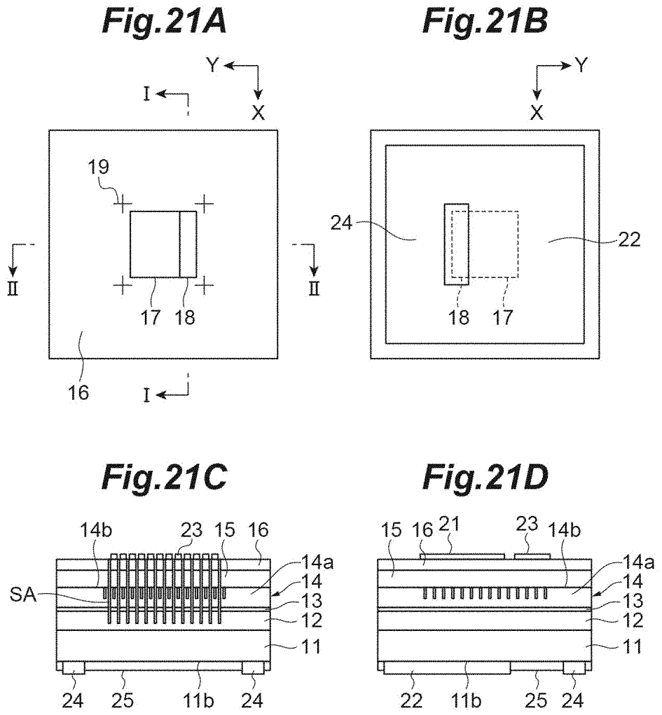

Here, an example of a method for manufacturing the light source module according to the present modification example will be described with reference to FIGS. 15A to 15D, FIGS. 16A to 16D, FIGS. 17A to 17D, FIGS. 18A to 18D, FIGS. 19A to 19D, FIGS. 20A to 20D, and FIGS. 21A to 21D. Note that FIG. 15A is a plan view, FIG. 15B is a bottom view, FIG. 15C is a schematic view of a cross section taken along line I-I of FIG. 15A, and FIG. 15D is a schematic view of a cross section taken along line II-II of FIG. 15A. FIG. 16A is a plan view, FIG. 16B is a bottom view, FIG. 16C is a schematic view of a cross section taken along line I-I of FIG. 16A, and FIG. 16D is a schematic view of a cross section taken along line II-II of FIG. 16A. FIG. 17A is a plan view, FIG. 17B is a bottom view, FIG. 17C is a schematic view of a cross section taken along line I-I of FIG. 17A, and FIG. 17D) is a schematic view of a cross section taken along line II-II of FIG. 17A. FIG. 18A is a plan view, FIG. 18B is a bottom view, FIG. 18C is a schematic view of a cross section taken along line I-I of FIG. 18A, and FIG. 18D is a schematic view of a cross section taken along line II-II of FIG. 18A. FIG. 19A is a plan view, FIG. 19B is a bottom view, FIG. 19C is a schematic view of a cross section taken along line I-I of FIG. 19A, and FIG. 19D is a schematic view of a cross section taken along line II-II of FIG. 19A. FIG. 20A is a plan view, FIG. 20B is a bottom view, FIG. 20C is a schematic view of a cross section taken along line I-I of FIG. 20A, and FIG. 20D is a schematic view of a cross section taken along line II-II of FIG. 20A. FIG. 21A is a plan view, FIG. 21B is a bottom view, FIG. 21C is a schematic view of a cross section taken along line I-I of FIG. 21A, and FIG. 21D is a schematic view of a cross section taken along line II-II of FIG. 21A.

First, as illustrated in FIGS. 15A to 15D, the epitaxial growth is performed to form the first cladding layer 12, the active layer 13, and the base layer 14a in this order on the main surface 11a of the semiconductor substrate 11 by using the MOCVD method. The positioning mark 19 is formed on the surface of the base layer 14a. Next, in the base layer 14a, a plurality of the modified refractive index regions 14b are formed in a region serving as the phase synchronization portion 17 and a region serving as the intensity modulation portion 18. A method for forming the modified refractive index region 14b is similar to that in the above-described embodiment. In this manner, the photonic crystal layer 14 having the base layer 14a and a plurality of the modified refractive index regions 14b is formed.

Subsequently, as illustrated in FIGS. 16A to 16D, the epitaxial growth is performed to form the second cladding layer 15 and the contact layer 16 in this order on the photonic crystal layer 14 by using the MOCVD method. As illustrated in FIGS. 17A to 17D, a plurality of the slits SA are formed in a region serving as the intensity modulation portion 18 in the active layer 13, the photonic crystal layer 14, the second cladding layer 15, and the contact layer 16. Specifically, first, a SiN film is formed on the contact layer 16, and a resist mask is formed on the SiN film by using an electron beam lithography technique with the mark 19 as a reference. The resist mask has an opening corresponding to the position and shape of the slit S on a region serving as the intensity modulation portion 18 in the contact layer 16. Dry etching (for example, reactive ion etching) is performed on the SiN film via the resist mask, and thus an etching mask comprised of SiN is formed. Dry etching (for example, inductively-coupled plasma etching) is performed on the contact layer 16, the second cladding layer 15, the photonic crystal layer 14, and the active layer 13 via the resist mask, and then the recess portions serving as a plurality of the slits SA are formed to a depth reaching the first cladding layer 12 through the contact layer 16, the second cladding layer 15, the photonic crystal layer 14, and the active layer 13. Note that the slit SA may be formed by filling the recess portion with a high resistor having a refractive index greater than that of the base layer 14a. Alternatively, a region having a high refractive index and a high resistance may be formed by performing ion implantation (for example, oxide ion implantation) via the etching mask instead of forming the slit SA. Through the above-described steps, the semiconductor stack portion 10 including the phase synchronization portion 17 and the intensity modulation portion 18 is formed.

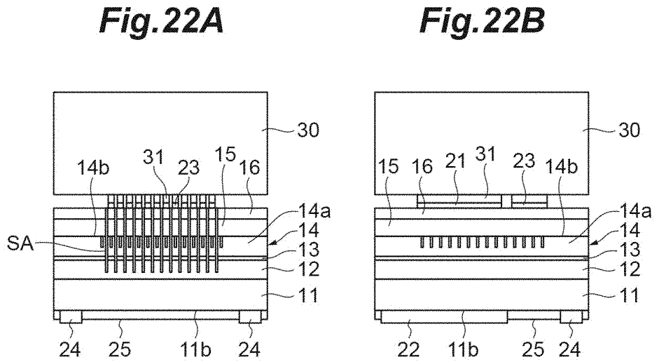

Subsequently, as illustrated in FIGS. 18A to 18D, the first electrode 21 is formed on the contact layer 16 included in the phase synchronization portion 17, and a plurality of the third electrodes 23 are formed on the contact layer 16 included in the intensity modulation portion 18. As illustrated in FIGS. 19A to 19D, the semiconductor substrate 11 is thinned by polishing the back surface 11b of the semiconductor substrate 11. As illustrated in FIGS. 20A to 20D, the antireflection film 25 is formed on the entire back surface 11b of the semiconductor substrate 11 by using a plasma CVD method. Openings corresponding to the second electrode 22 and the fourth electrode 24 are formed on the antireflection film 25 by using a photolithography technique with the mark 19 as a reference. As illustrated in FIGS. 21A to 21D, the second electrode 22 is formed on the back surface 11b of the semiconductor substrate 11 included in the phase synchronization portion 17, and the fourth electrode 24 is formed on the back surface 11b of the semiconductor substrate 11 included in the intensity modulation portion 18. The light source module according to the present modification example is manufactured through the above-described steps. Thereafter, as illustrated in FIGS. 22A and 22B, the light source module is flip-chip mounted on the control circuit board 30 as necessary. Note that FIG. 22A is a schematic view corresponding to the I-I cross section illustrated in FIGS. 15A, 16A, 17A, 18A, 19A, 20A, and 21A, and FIG. 22B is a schematic view corresponding to the II-II cross section illustrated in FIGS. 15A, 16A, 17A, 18A, 19A, 20A, and 21A. The second electrode 22 and the fourth electrode 24 are connected to the control circuit board 30 by wire bonding.

As in the present modification example, the slit SA may be formed so as to divide the photonic crystal layer 14 and the active layer 13 from the surface of the semiconductor stack portion 10. Even in this case, it is possible to achieve the same operational effects as those of the above-described embodiment. Furthermore, since the slit SA electrically and optically divides the second cladding layer 15 and the contact layer 16, an electrical and optical crosstalk between the subpixels Pb adjacent to each other is further decreased.

### Second Modification Example

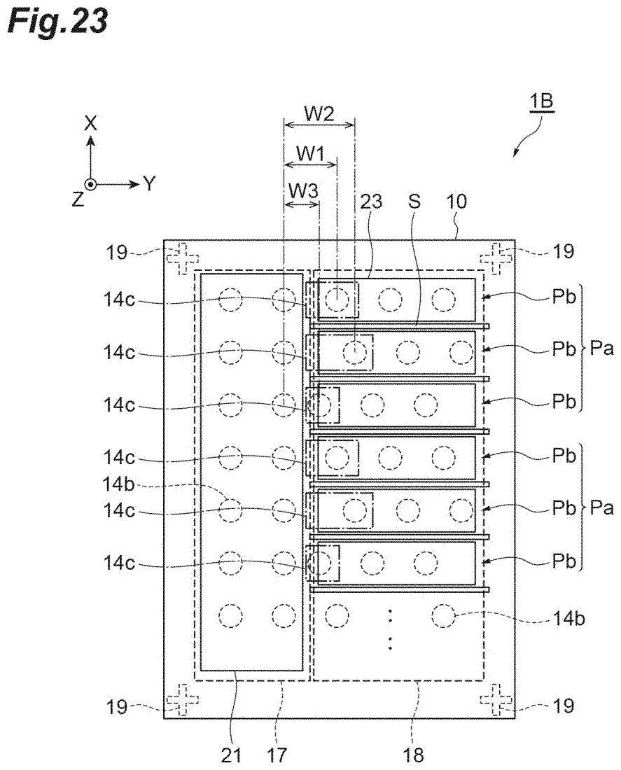

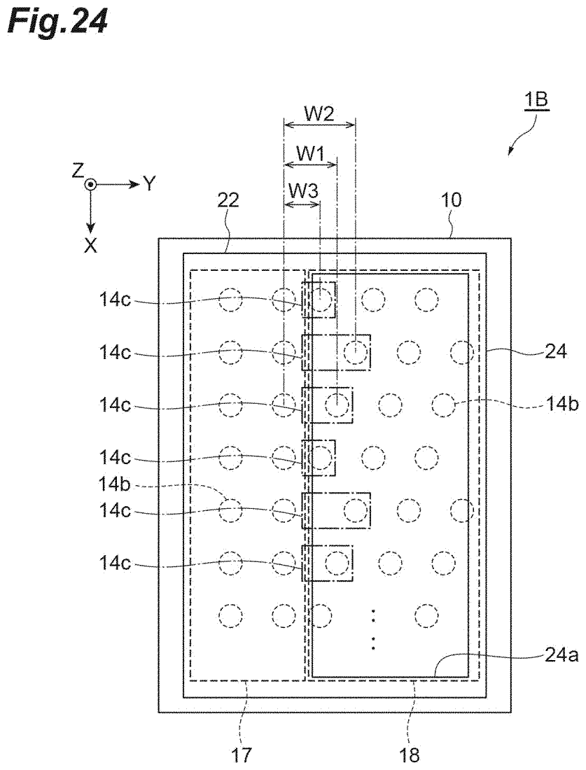

FIG. 23 is a plan view of a light source module 1B according to the second modification example of the above-described embodiment. FIG. 24 is a bottom view of the light source module 1B. Note that a cross-sectional configuration of the light source module 1B is similar to that of the above-described embodiment, and is thus will not be illustrated.

A difference between the present modification example and the above-described embodiment is a structure of the photonic crystal layer 14 in the intensity modulation portion 18. That is, in the present modification example, the photonic crystal layer 14 includes a phase shift portion 14c provided in one-to-one correspondence with the N₁ subpixels Pb, and the phase shift portion 14c makes phases of the laser light beams L outputted from the pixels Pa in the Y-direction different from each other between N₁ subpixels Pb.

A specific description will be made with reference to FIG. 23. Three subpixels Pb included in each pixel Pa have the photonic crystal layer 14 including a plurality of the modified refractive index regions 14b. A plurality of the modified refractive index regions 14b included in the photonic crystal layer 14 of each subpixel Pb are arranged in the Y-direction. The center interval (lattice point interval), which is defined in the Y-direction, between certain one modified refractive index region 14b included in the photonic crystal layer 14 of one subpixel Pb and another modified refractive index region 14b located on the phase synchronization portion 17 side (or inside the phase synchronization portion 17) with respect to the modified refractive index region 14b is W1. Similarly, center intervals W2 and W3 are set for the other two subpixels Pb. In this case, the phase shift portion 14c described above is realized by making the center intervals W1 to W3 different from each other.

These center intervals are set such that a phase difference between the laser light beams L outputted from the subpixels Pb becomes an integer multiple of 2π/N₁. In a case of N₁=3, the center intervals W1 to W3 are set such that a phase difference between the laser light beams L outputted from the subpixels Pb becomes an integer multiple of 2π/3. In one example, one of the center intervals W1 to W3 is set to be ⅔ times (or 5/3 times) the lattice interval a, another one is set be to 4/3 times the lattice interval a, and the remaining one is set to be equal to the lattice interval a. In other words, a difference between the center interval W1 and the center interval W2, and a difference between the center interval W2 and the center interval W3 are set to be ⅓ times the lattice interval a. Note that as described above, in a case where Γ-point oscillation occurs in the photonic crystal layer 14, the lattice interval a is equal to λ/n (λ: emission wavelength, n: effective refractive index of photonic crystal layer 14). An arrangement order of three subpixels Pb is determined regardless of the center interval.

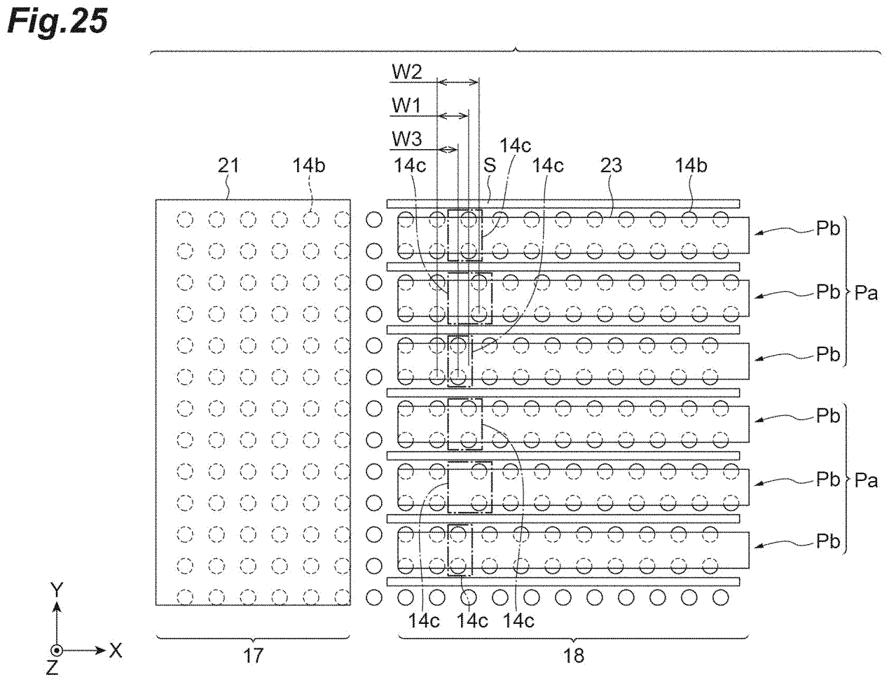

FIG. 25 is a plan view illustrating all of sizes and positional relationships of the modified refractive index region 14b, the first electrode 21, the third electrode 23, and the slit S at the same magnification as an example of the present modification example. In the example illustrated in FIG. 25, the modified refractive index regions 14b of 13 rows and 6 columns (78 in total) overlap with the first electrode 21 to form the photonic crystal layer 14 of the phase synchronization portion 17. Furthermore, the modified refractive index regions 14b of 2 rows and 11 columns (22 in total) overlap with the third electrode 23 to form the photonic crystal layer 14 of the subpixel Pb. A portion (phase shift portion 14c) in which the interval between the modified refractive index regions 14b adjacent to each other in the Y-direction is different for each subpixel Pb is provided for each subpixel Pb. In this example, the center interval W1 is set to be ⅔ times the lattice interval a, the center interval W2 is set to be 4/3 times the lattice interval a, and the center interval W3 is set to be equal to the lattice interval a.

Note that in the example illustrated in FIG. 25, the planar shape of the modified refractive index region 14b is circular, a diameter thereof is, for example, 71.9 nm, and the center interval (that is, the lattice interval a) is, for example, 285 nm. A ratio (filling factor) of the modified refractive index region 14b in the area of a unit constituent region R is, for example, 20%. A width of the slit S, which is defined in the X-direction, is, for example, 65 nm (0.228 a). Note that the width of the slit S and the diameter of the modified refractive index region 14b are determined based on a condition that the recess portion of the modified refractive index region 14b is inside the base layer 14a and the recess portion of the slit S reaches the first cladding layer 12 when the slit S and the modified refractive index region 14b are simultaneously formed by etching. The width of the third electrode 23, which is defined in the X-direction, is, for example, 300 nm.

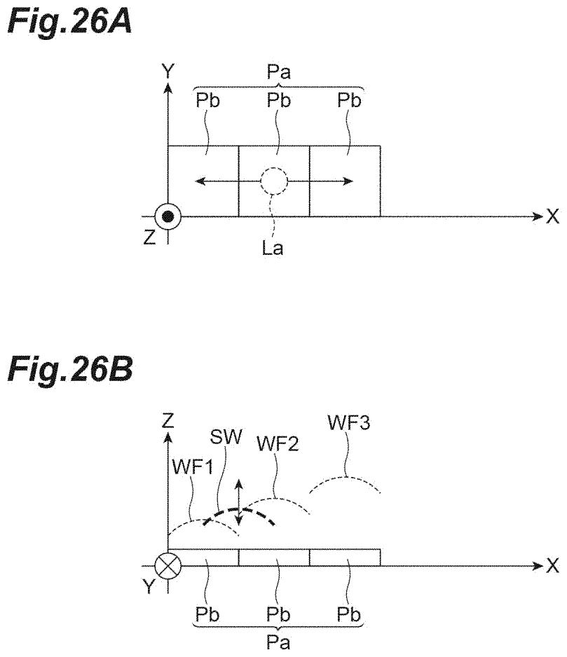

As in the present modification example, the photonic crystal layer 14 of each subpixel Pb may include the phase shift portion 14c for making the phase of the laser light beam L outputted from each pixel Pa different from each other between N₁ subpixels Pb. In this case, the phase of the laser light beam L outputted from each pixel Pa in the Y-direction is different for each subpixel Pb. The phase of the laser light beam L outputted from each pixel Pa in the Y-direction is determined in accordance with the intensity distribution and the phase distribution of N₁ subpixels Pb constituting the pixel Pa. In this case, the phase of the laser light beam L in the Y-direction can be dynamically modulated, but an optical wave traveling in the Y-direction is diffracted in the Z-direction due to the diffraction effect of the modified refractive index region 14b in the intensity modulation portion 18. Therefore, as a result, the phase in the Z-direction can also be dynamically modulated. That is, it is possible to dynamically modulate the phase distribution of the light in an output direction, and the degree of freedom of controlling the phase distribution of the laser light beam L is further increased. That is, as illustrated in FIG. 26A, in the above-described embodiment, a spatial phase of a light emission point La on the surface in a primary direction (X-direction) is controlled, but in the present modification example, as illustrated in FIG. 26B, a phase of a synthesized wave front SW of wave fronts WF1 to WF3 traveling in a direction perpendicular to the plane (Z-direction) from each subpixel Pb can be controlled.

### Third Modification Example

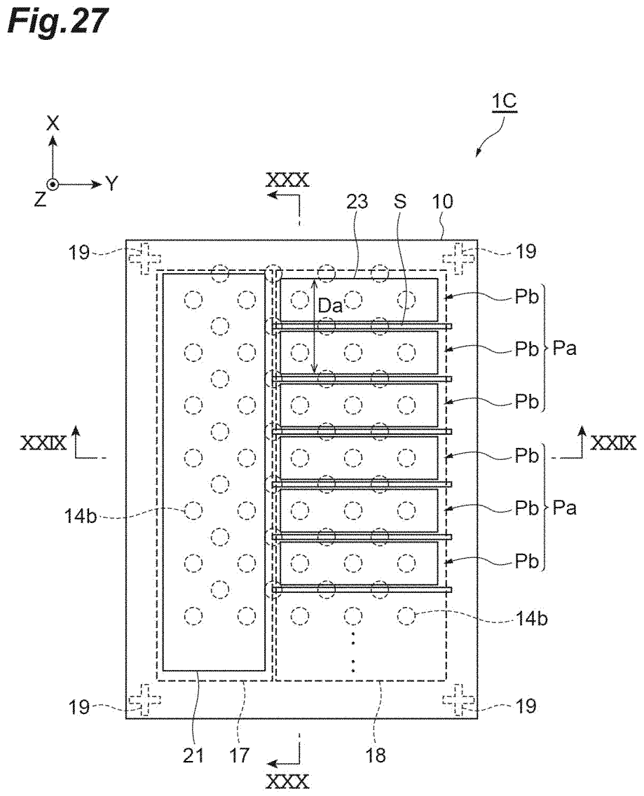

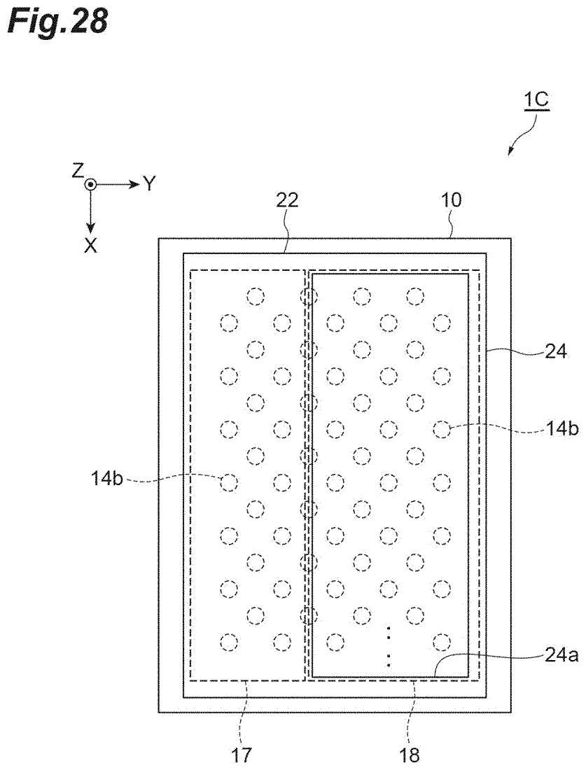

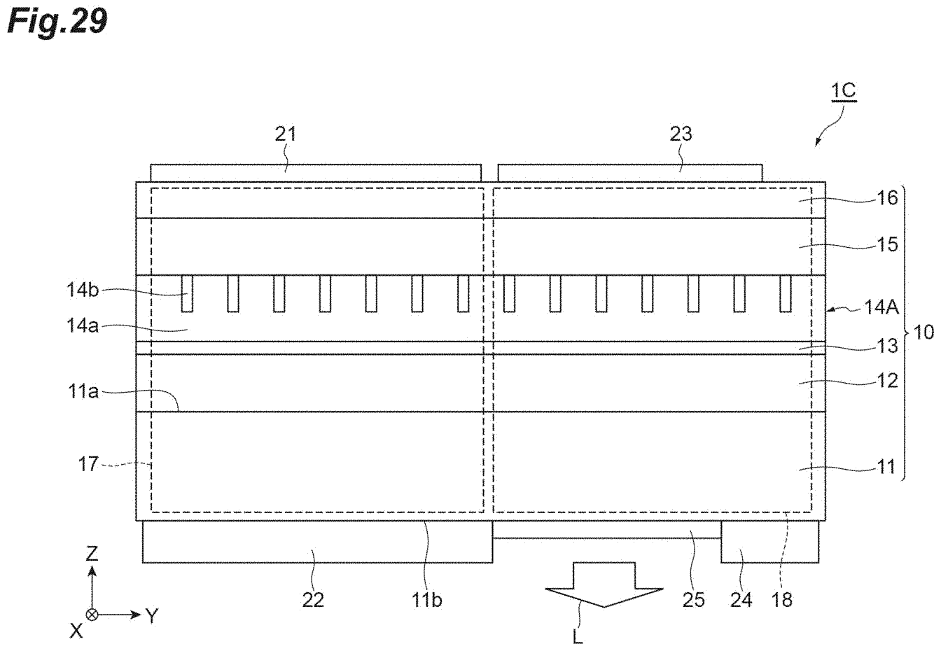

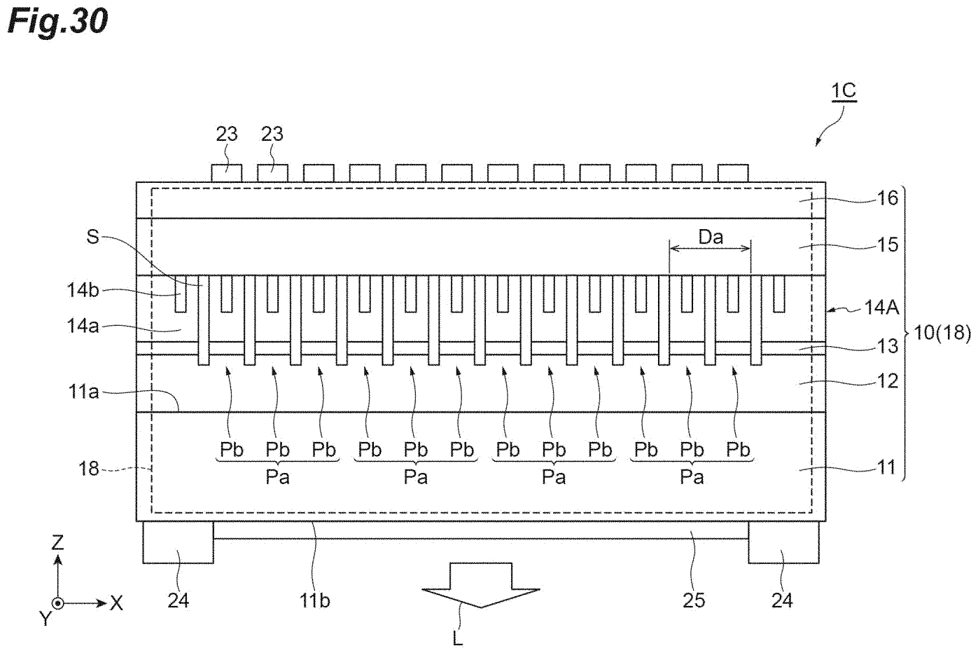

FIG. 27 is a plan view of a light source module 1C according to the third modification example of the above-described embodiment. FIG. 28 is a bottom view of the light source module 1C. FIG. 29 is a view schematically illustrating a cross section taken along line XXIX-XXIX of FIG. 27. FIG. 30 is a view schematically illustrating a cross section taken along line XXX-XXX of FIG. 27. The light source module 1C of the present modification example includes a resonance mode forming layer 14A instead of the photonic crystal layer 14 of the above-described embodiment. The arrangement of the resonance mode forming layer 14A is similar to that of the photonic crystal layer 14 of the above-described embodiment. Other configurations of the light source module 1C except the resonance mode forming layer 14A are similar to those of the light source module 1A of the above-described embodiment.

Furthermore, a form of the modified refractive index region 14b and a method for forming the modified refractive index region 14b are similar to those in the above-described embodiment.

The resonance mode forming layer 14A has a two-dimensional diffraction lattice. The resonance mode forming layer 14A includes a base layer 14a and a plurality of modified refractive index regions 14b provided inside the base layer 14a. Refractive indexes of the modified refractive index regions 14b are different from the refractive index of the base layer 14a. The modified refractive index regions 14b are disposed at constant intervals in a direction inclined at 45° with respect to the X-direction and inclined at 45° from the Y-direction in the base layer 14a. A configuration of each of the modified refractive index regions 14b is similar to that in the above-described embodiment.

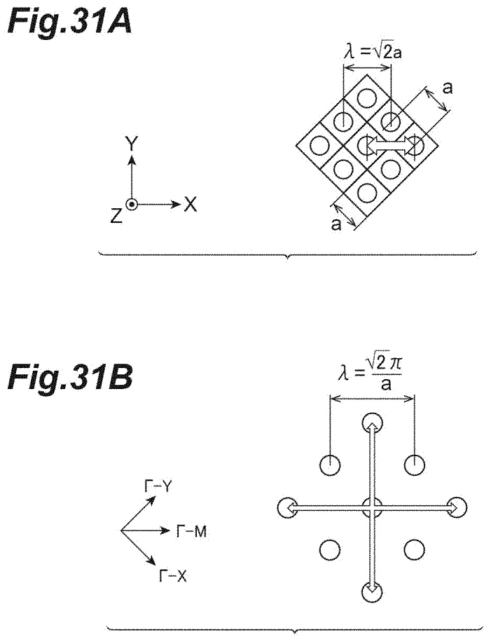

The resonance mode forming layer 14A of the phase synchronization portion 17 has a photonic crystal structure in which a plurality of the modified refractive index regions 14b are periodically arranged. The modified refractive index regions 14b are disposed at intervals so as to satisfy a condition of M-point oscillation with respect to the emission wavelength of the active layer 13. FIG. 31A is a diagram for explaining the M-point oscillation in the real space. FIG. 31B is a diagram for explaining the M-point oscillation in a reciprocal lattice space. The circles illustrated in FIGS. 31A and 31B represent the modified refractive index regions 14b.

FIG. 31A illustrates a case where the modified refractive index region 14b is located at an opening center of the lattice frame of the square lattice in the real space in which an XYZ three-dimensional orthogonal coordinate system is set. The lattice interval of the square lattice is a, the gravity center interval of the modified refractive index regions 14b adjacent in the X-axis direction and the Y-axis direction is 2^{0.5} a, and a value λ/n obtained by dividing the emission wavelength λ by an effective refractive index n is 2^{0.5} times a (λ/n=a×2^{0.5}). In this case, the oscillation at a point M occurs in the photonic crystal structure of the resonance mode forming layer 14A. At this time, the laser light beam is outputted in the X-axis direction and the Y-axis direction, and the laser light beam is not outputted in the Z-axis direction. FIG. 31B illustrates a reciprocal lattice of the lattice of FIG. 31A, and the interval between the modified refractive index regions 14b adjacent in a Γ-M direction is (2^{0.5}π)/a, which coincides with 2nₑ π/λ (nₑ is the effective refractive index of the photonic crystal layer 14). Note that white arrows in FIGS. 31A and 31B indicate traveling directions of light waves.

In the example described above, the case where the modified refractive index region 14b is located at the opening center of the lattice frame of the square lattice has been described, but the modified refractive index region 14b may be located at the opening center of the lattice frame of another lattice (for example, a triangular lattice).

The intensity modulation portion 18 of the present embodiment has a configuration as a so-called static-integrable phase modulating (S-iPM) laser. Each pixel Pa outputs the laser light beam L in a direction perpendicular to the main surface 11a of the semiconductor substrate 11 (that is, the Z-direction), a direction inclined with respect to the direction perpendicular to the main surface 11a of the semiconductor substrate 11, or a direction including both the directions. Hereinafter, the configuration of the resonance mode forming layer 14A of the intensity modulation portion 18 will be described in detail.

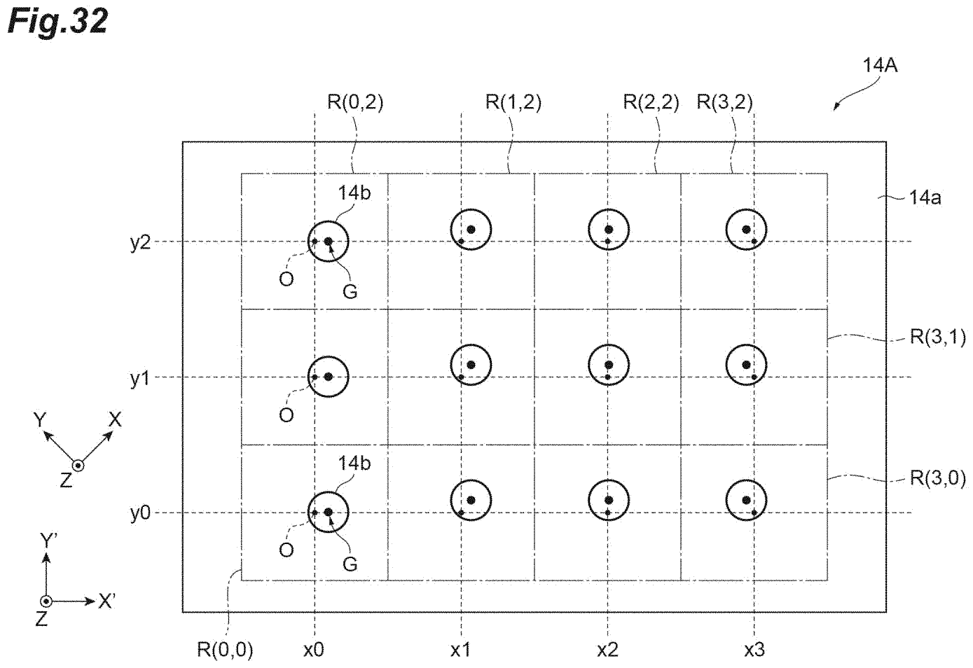

FIG. 32 is a plan view of the resonance mode forming layer 14A of the intensity modulation portion 18. As illustrated in FIG. 32, the resonance mode forming layer 14A includes a base layer 14a and a plurality of modified refractive index regions 14b having a refractive index different from that of the base layer 14a. In FIG. 32, a virtual square lattice on an X′-Y′ plane is set for the resonance mode forming layer 14A. An X′-axis rotates by 45° about a Z-axis with respect to the X′-axis, and a Y′-axis rotates by 45° about the Z-axis with respect to the Y′-axis. One side of the square lattice is parallel to the X′-axis, and the other side is parallel to the Y′-axis. Square-shaped unit constituent regions R (0, 0) to R (3, 2) centered on a lattice point O of the square lattice (intersection point of lines x0 to x3 parallel to the Y′-axis and lines y0 to y2 parallel to the X′-axis) are two-dimensionally arranged over a plurality of columns along the X′-axis and a plurality of rows along the Y′-axis. That is, the X′-Y′ coordinates of each unit constituent region R is defined by a gravity center position of each unit constituent region R. The gravity center positions coincide with the lattice point O of the virtual square lattice. For example, each of the modified refractive index regions 14b is provided in each unit constituent region R one by one. The lattice point O may be located outside the modified refractive index region 14b or may be included inside the modified refractive index region 14b.

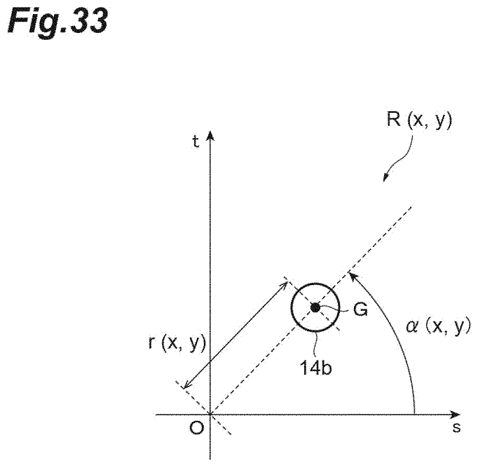

FIG. 33 is an enlarged view of the unit constituent region R (x, y). As illustrated in FIG. 33, each of the modified refractive index regions 14b has a gravity center G. The position in the unit constituent region R (x, y) is defined by coordinates defined by an s-axis (axis parallel to the X′-axis) and a t-axis (axis parallel to the Y′-axis). An angle formed by a vector from the lattice point O toward the gravity center G and the s-axis (axis parallel to the X′-axis) is defined as a (x, y). x represents a position of an x-th lattice point on the X′-axis, and y represents a position of a y-th lattice point on the Y′-axis. In a case where an angle α is 0°, a direction of the vector connecting the lattice point O with the gravity center G coincides with a positive direction of the X′-axis. Furthermore, a length of the vector connecting the lattice point O with the gravity center G is r (x, y). In one example, r (x, y) is constant throughout the resonance mode forming layer 14A regardless of x and y.

As illustrated in FIG. 32, the direction of the vector connecting the lattice point O with the gravity center G, that is, the angle α around the lattice point O of the gravity center G of the modified refractive index region 14b is individually set for each lattice point O according to a phase distribution φ(x, y) in accordance with the desired shape of the output light. In the present disclosure, such an arrangement mode of the gravity center G is referred to as a first mode. The phase distribution φ (x, y) has a specific value for each position determined by the values of x and y, but is not necessarily represented by a specific function. An angle distribution a (x, y) is determined by extracting the phase distribution φ (x, y) from a complex amplitude distribution obtained by Fourier transforming the desired shape of the output light. When the complex amplitude distribution is obtained from the desired shape of the output light, an iterative algorithm such as a Gerchberg-Saxton (GS) method generally used at the time of calculation for hologram generation may be applied. In this case, it is possible to improve the reproducibility of the beam pattern.

The angle distribution a (x, y) of the modified refractive index region 14b in the resonance mode forming layer 14A is determined by, for example, the following procedure.

As a first precondition, a virtual square lattice configured by M1×N1 (M1 and N1 are integers of one or more) unit constituent regions R having a square shape is set on an X′-Y′ plane in the X′Y′Z orthogonal coordinate system defined by the Z-axis coinciding with the normal direction of the main surface 11a and the X′-Y′ plane coinciding with one surface of the resonance mode forming layer 14A including a plurality of the modified refractive index regions 14b.

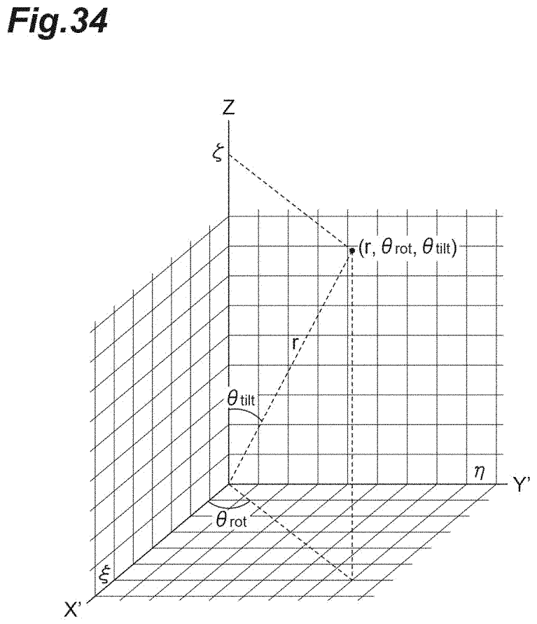

As a second precondition, it is assumed that the coordinates (ξ, η, ζ) in the X′Y′Z orthogonal coordinate system satisfy the relationships represented by the following Formulas (1) to (3) with respect to the spherical coordinates (r, θᵣₒₜ, θₜᵢₗₜ) defined by a radial length r, an inclination angle θₜᵢₗₜ from the Z-axis, and a rotation angle θᵣₒₜ from the X′-axis specified on the X′-Y′plane as illustrated in FIG. 34. FIG. 34 is a diagram for explaining coordinate transformation from the spherical coordinates (r, θᵣₒₜ, θₜᵢₗₜ) to the coordinates (ξ, η, ζ) in the X′Y′Z orthogonal coordinate system, and the coordinates (ξ, η, ζ) represent a designed optical image on a predetermined plane set in the X′Y′Z orthogonal coordinate system that is a real space.

ξ=r sin θₜᵢₗₜ cos θᵣₒₜ (1)

η=r sin θₜᵢₗₜ sin θᵣₒₜ (2)

ζ=r cos θₜᵢₗₜ (3)

When the laser light beam L outputted from the light source module 1C is a set of bright spots directed in a direction defined by angles θₜᵢₗₜ and θᵣₒₜ, the angles θₜᵢₗₜ and θᵣₒₜ are converted into a coordinate value kx on a K_{X}-axis corresponding to the X′-axis, which is a normalized wave number defined by the following Formula (4), and a coordinate value ky on a K_{Y}-axis corresponding to the Y′-axis and orthogonal to the K_{X}-axis, which is a normalized wave number defined by the following Formula (5). The normalized wave number means a wave number normalized with a wave number 2π/a corresponding to the lattice interval of the virtual square lattice as 1.0. At this time, in a wave-number space defined by the K_{X}-axis and the K_{Y}-axis, a specific wave number range including the beam pattern corresponding to the laser light beam L includes M2×N2 (M2 and N2 are integers of one or more) image regions each having a square shape. Note that the integer M2 does not need to coincide with the integer M1. Similarly, the integer N2 does not need to coincide with the integer N1. Formulas (4) and (5) are disclosed in, for example, Non-Patent Document 3 described above.

$${k}_{x} = \frac{a}{λ} sin {θ}_{tilt} cos {θ}_{rot} \qquad ( 4 )$$

$${k}_{y} = \frac{a}{λ} sin {θ}_{tilt} sin {θ}_{rot} \qquad ( 5 )$$

a: Lattice constant of virtual square lattice

λ: Oscillation wavelength of light source module 1C

As a third precondition, in the wave-number space, a complex amplitude distribution F (x, y) obtained by performing two-dimensional inverse discrete Fourier transform of each of image regions FR (kx, ky) specified by a coordinate component kx (an integer of zero or more and M2-1 or less) in the K_{X}-axis direction and a coordinate component ky (an integer of zero or more and N2-1 or less) in the K_{Y}-axis direction into a unit constituent region R (x, y) on the X′-Y′ plane specified by a coordinate component x (an integer of zero or more and M1-1 or less) in the X′-axis direction and a coordinate component y (an integer of zero or more and N1-1 or less) in the Y′-axis direction is given by the following Formula (6) with j as an imaginary unit. The complex amplitude distribution F (x, y) is defined by the following Formula (7) when the amplitude distribution is A (x, y) and the phase distribution is φ (x, y). As a fourth precondition, the unit constituent region R (x, y) is defined by an s-axis and a t-axis, which are parallel to the X′-axis and the Y′-axis, respectively and orthogonal in the lattice point O (x, y) as the center of the unit constituent region R (x, y).

$$F ( x , y ) = {\sum }_{{k}_{x} = 0}^{M 2 - 1} {\sum }_{{k}_{y} = 0}^{N 2 - 1} FR ( {k}_{x} , {k}_{y} ) exp [ j 2 π ( \frac{{k}_{x}}{M 2} x + \frac{{k}_{y}}{N 2} y ) ] \qquad ( 6 )$$

$$F ( x , y ) = A ( x , y ) ⨯ exp [ j ϕ ( x , y ) ] \qquad ( 7 )$$

Under the first to fourth preconditions, the resonance mode forming layer 14A of the intensity modulation portion 18 is configured to satisfy the following fifth condition or sixth condition. That is, the fifth condition is satisfied by disposing the gravity center G away from the lattice point O (x, y) in the unit constituent region R (x, y). The sixth condition is satisfied by disposing the corresponding modified refractive index region 14b inside the unit constituent region R (x, y) such that in a state in which a line segment length r₂ (x, y) from the lattice point O (x, y) to the corresponding gravity center G is set to a common value in each of M1×N1 unit constituent regions R, an angle α (x, y) formed by a line segment connecting the lattice point O (x, y) with the corresponding gravity center G and the s-axis satisfies

α(x,y)=C×φ(x,y)+B,

where

C: Proportional constant, for example, 180°/π

B: Arbitrary constant, for example, zero.

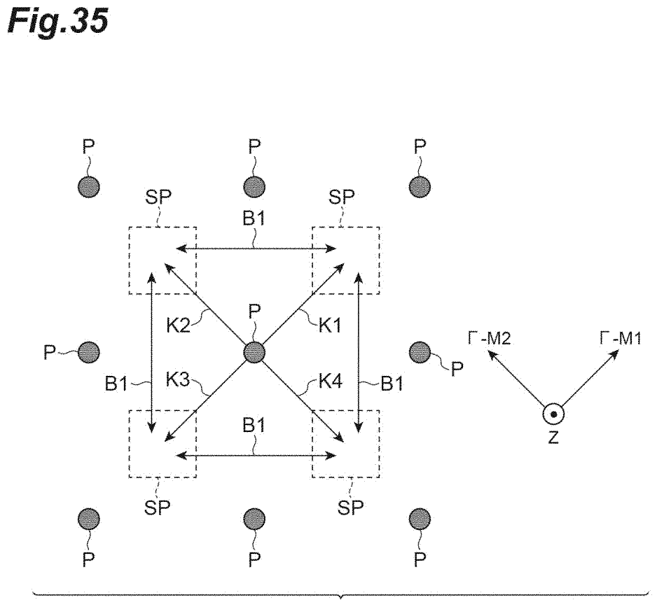

Next, the M-point oscillation of the resonance mode forming layer 14A of the intensity modulation portion 18 will be described. As described above, for the M-point oscillation, the lattice interval a of the virtual square lattice, the emission wavelength λ of the active layer 13, and the equivalent refractive index n of the mode may satisfy the condition of λ=(2^{0.5})n×a. FIG. 35 is a plan view illustrating the reciprocal lattice space related to the phase modulation layer of a light emitting device that performs M-point oscillation. A point P in FIG. 35 represents a reciprocal lattice point. Arrows B1 in FIG. 35 represent basic reciprocal lattice vectors, and arrows K1, K2, K3, and K4 represent four in-plane wave number vectors. The in-plane wave number vectors K1 to K4 each have a wave number spread SP due to an angle distribution α(x, y).

The magnitudes of the in-plane wave number vectors K1 to K4 (that is, the magnitude of a stationary wave in the in-plane direction) are smaller than the magnitude of a basic reciprocal lattice vector B1. Therefore, a vector sum of the in-plane wave number vectors K1 to K4 and the basic reciprocal lattice vector B1 does not become zero, and the wave number in the in-plane direction cannot become zero due to the diffraction, so that the diffraction does not occur in a direction perpendicular to the plane (Z-axis direction). In this state, not only zero-order light in the direction perpendicular to the plane (Z-axis direction) but also +1st-order light and −1st-order light in a direction inclined with respect to the Z-axis direction are not outputted in each pixel Pa of the M-point oscillation.

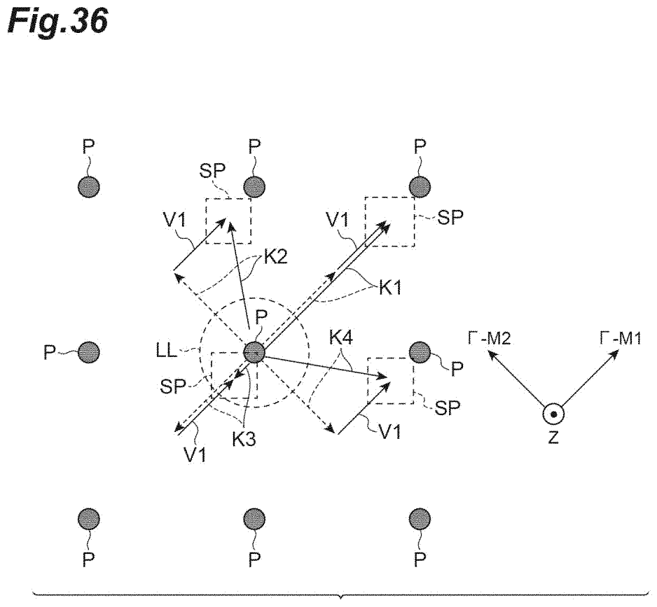

In the present embodiment, the following action is taken on the resonance mode forming layer 14A of the intensity modulation portion 18, and thus a part of the +1st-order light and −1st-order light is outputted from each pixel Pa. That is, as illustrated in FIG. 36, by adding a diffraction vector V1 having a certain constant magnitude and direction to the in-plane wave number vectors K1 to K4, the magnitude of at least one of the in-plane wave number vectors K1 to K4 (in-plane wave number vector K3 in FIG. 36) becomes smaller than 2π/λ (λ: wavelength of light outputted from the active layer 13). In other words, at least one of the in-plane wave number vectors K1 to K4 to which the diffraction vector V1 is added falls within a light line LL that is a circular region having a radius of 2π/λ.

In FIG. 36, the in-plane wave number vectors K1 to K4 indicated by broken lines represent values before addition of the diffraction vector V1, and in-plane wave number vectors K1 to K4 indicated by solid lines represent values obtained after addition of the diffraction vector V1. The light line LL corresponds to a total reflection condition, and a wave number vector having the magnitude within the light line LL has a component in the direction perpendicular to the plane (Z-axis direction). In an example, the direction of the diffraction vector V1 is along the Γ-M1 axis or the Γ-M2 axis. The magnitude of the diffraction vector V1 is in a range of 2π/(2^{0.5})a−2π/λ to 2π/(2^{0.5})a+2π/λ, and is 2π/(2^{0.5})a in one example.

Subsequently, the size and direction of the diffraction vector V1 for accommodating at least one of the in-plane wave number vectors K1 to K4 within the light line LL will be examined. The following Formulas (8) to (11) represent the in-plane wave number vectors K1 to K4 before the diffraction vector V1 is added.

$$K 1 = ( \frac{π}{a} + Δ kx , \frac{π}{a} + Δ ky ) \qquad ( 8 )$$

$$K 2 = ( - \frac{π}{a} + Δ kx , \frac{π}{a} + Δ ky ) \qquad ( 9 )$$

$$K 3 = ( - \frac{π}{a} + Δ kx , - \frac{π}{a} + Δ ky ) \qquad ( 10 )$$

$$K 4 = ( \frac{π}{a} + Δ kx , - \frac{π}{a} + Δ ky ) \qquad ( 11 )$$

The wave number vector spreads Δkx and Δky satisfy the following Formulas (12) and (13), respectively. A maximum value Δkxₘₐₓ of the spread of the in-plane wave number vector in the X′-axis direction and the maximum value Δkyₘₐₓ of the spread of the in-plane wave number vector in the Y′-axis direction are defined by the angular spread of the designed optical image.

−Δkxₘₐₓ≤Δkx≤Δkxₘₐₓ (12)

−Δkyₘₐₓ≤Δky≤Δkyₘₐₓ (13)

When the diffraction vector V1 is represented by the following Formula (14), the in-plane wave number vectors K1 to K4 to which the diffraction vector V1 is added are represented by the following formulas (15) to (18).

$$V = ( Vx , Vy ) \qquad ( 14 )$$

$$K 1 = ( \frac{π}{a} + Δ kx + Vx , \frac{π}{a} + Δ ky + Vy ) \qquad ( 15 )$$

$$K 2 = ( - \frac{π}{a} + Δ kx + Vx , \frac{π}{a} + Δ ky + Vy ) \qquad ( 16 )$$

$$K 3 = ( - \frac{π}{a} + Δ kx + Vx , - \frac{π}{a} + Δ ky + Vy ) \qquad ( 17 )$$

$$K 4 = ( \frac{π}{a} + Δ kx + Vx , - \frac{π}{a} + Δ ky + Vy ) \qquad ( 18 )$$

Considering that any of the in-plane wave number vectors K1 to K4 falls within the light line LL in the above-described Formulas (15) to (18), the relationship of the following Formula (19) is established.

$${( \pm \frac{π}{a} + Δ kx + Vx )}^{2} + {( \pm \frac{π}{a} + Δ ky + Vy )}^{2} < {( \frac{2 π}{λ} )}^{2} \qquad ( 19 )$$

That is, by adding the diffraction vector V1 that satisfies Formula (19), any of the in-plane wave number vectors K1 to K4 falls within the light line LL, and a part of the +1st-order light and −1st-order light is outputted.

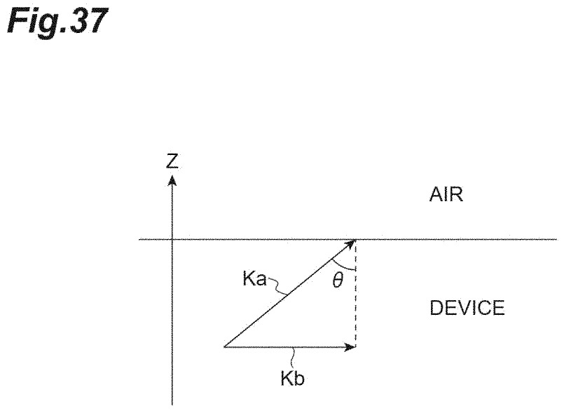

The size (radius) of the light line LL is set to 2π/λ for the following reasons. FIG. 37 is a diagram for schematically explaining a peripheral structure of the light line LL. FIG. 37 illustrates a boundary between a device located in the Z-direction and air. The magnitude of the wave number vector of the light in vacuum is 2π/λ, but when the light propagates through a device medium as illustrated in FIG. 37, the magnitude of a wave number vector Ka in the medium having a refractive index n is 2πn/λ. At this time, in order for light to propagate through the boundary between the device and the air, a wave number component parallel to the boundary needs to be continuous (wave number conservation law).

In FIG. 37, in a case where the wave number vector Ka and the Z-axis form an angle θ, a length of the wave number vector (that is, the in-plane wave number vector) Kb projected onto the plane is (2πn/λ) sin θ. On the other hand, since the refractive index n of the medium is generally greater than one, the wave number conservation law does not hold at an angle at which the in-plane wave number vector Kb in the medium is greater than 2π/λ. At this time, the light is totally reflected and cannot be extracted to an air side. The magnitude of the wave number vector corresponding to the total reflection condition is the size of the light line LL, that is, 2π/λ.

As an example of a specific method of adding the diffraction vector V1 to the in-plane wave number vectors K1 to K4, a method of superimposing the phase distribution φ₂ (x, y) irrelevant to a desired output light shape on a phase distribution φ₁ (x, y) according to the desired output light shape is considered. In this case, the phase distribution φ (x, y) of the resonance mode forming layer 14A of the intensity modulation portion 18 is represented as φ (x, y)=φ₁ (x, y)+φ₂ (x, y). φ₁ (x, y) corresponds to a phase of complex amplitude when a desired shape of the output light is Fourier-transformed as described above. Furthermore, φ₂ (x, y) is a phase distribution for adding the diffraction vector V1 satisfying the above-described Formula (19). Note that the phase distribution φ₂ (x, y) of the diffraction vector V1 is represented by an inner product of a diffraction vector V1 (Vx, Vy) and a position vector r (x, y), and is given with the following Formula.

φ₂(x,y)=V1·r=Vxx+Vyy

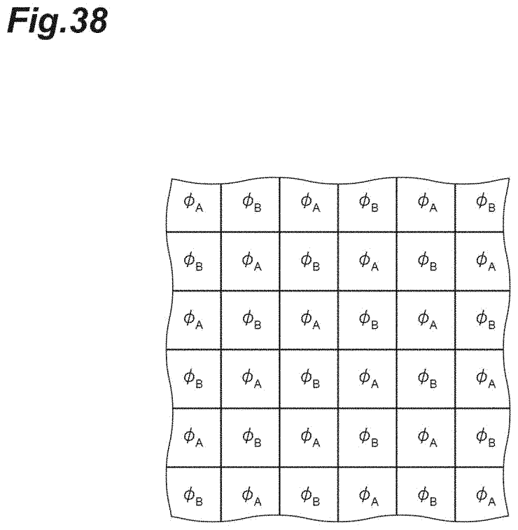

FIG. 38 is a diagram conceptually illustrating an example of the phase distribution φ₂ (x, y). In the example of FIG. 38, a first phase value φ_{A} and a second phase value φ_{B} having a value different from the first phase value φ_{A} are arranged in a check pattern. In one example, the phase value φ_{A} is zero (rad), and the phase value φ_{B} is π (rad). In this case, the first phase value φ_{A} and the second phase value φ_{B} change by π. By such an arrangement of the phase values, the diffraction vector V1 along the Γ-M1 axis or the Γ-M2 axis can be suitably realized. In the case of the checkered arrangement, V1=(±π/a, ±π/a), and the diffraction vector V1 and any one of the in-plane wave number vectors K1 to K4 in FIG. 36 are exactly offset. Therefore, a symmetry axis of the +1st-order light and −1st-order light coincides with the Z-direction, that is, a direction perpendicular to the direction defined on the plane of the resonance mode forming layer 14A. Furthermore, by changing the arrangement direction of the phase values φ_{A} and φ_{B} from 45°, the direction of the diffraction vector V1 can be adjusted to an arbitrary direction. Note that as described above, the diffraction vector V1 may be shifted from (±π/a, ±π/a) as long as at least one of the in-plane wave number vectors K1 to K4 falls within the range of the light line LL.

In the present modification example, in a case where the wave number spread based on the angular spread of the output light is included in a circle having a radius Δk centered on a certain point on the wave-number space, the wave number spread can be simply considered as follows. By adding the diffraction vector V1 to the in-plane wave number vectors K1 to K4 in four directions, the magnitude of at least one of the in-plane wave number vectors K1 to K4 in the four directions becomes smaller than 2π/λ (light line LL). This may be considered that by adding the diffraction vector V1 to a vector obtained by removing a wave number spread Δk from the in-plane wave number vectors K1 to K4 in the four directions, the magnitude of at least one of the in-plane wave number vectors K1 to K4 in the four directions is smaller than a value {(2π/λ)−Δk} obtained by subtracting the wave number spread Δk from 2π/λ.

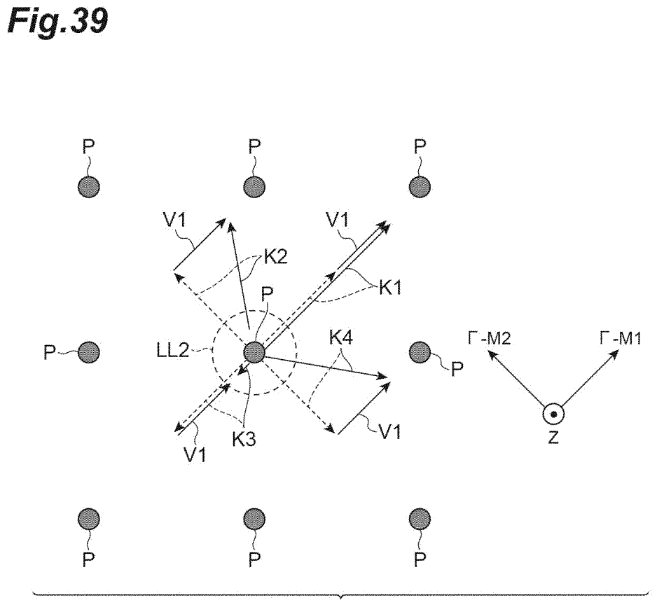

FIG. 39 is a diagram conceptually illustrating the above-described idea. As illustrated in FIG. 39, when the diffraction vector V1 is added to the in-plane wave number vectors K1 to K4 obtained by removing the wave number spread Δk, the magnitude of at least one of the in-plane wave number vectors K1 to K4 becomes smaller than {(2π/λ)−Δk}. In FIG. 39, a region LL2 is a circular region having a radius of {(2π/λ)−Δk}. In FIG. 39, the in-plane wave number vectors K1 to K4 indicated by broken lines represent values before addition of the diffraction vector V1, and the in-plane wave number vectors K1 to K4 indicated by solid lines represent values obtained after addition of the diffraction vector V1. The region LL2 corresponds to a total reflection condition in consideration of the wave number spread Δk, and a wave number vector having the magnitude within the region LL2 is propagated also in the direction perpendicular to the plane (Z-axis direction).

In this mode, the magnitude and direction of the diffraction vector V1 for accommodating at least one of the in-plane wave number vectors K1 to K4 within the region LL2 will be explained. The following Formulas (20) to (23) represent the in-plane wave number vectors K1 to K4 before the diffraction vector V1 is added.

$$K 1 = ( \frac{π}{a} , \frac{π}{a} ) \qquad ( 20 )$$

$$K 2 = ( - \frac{π}{a} , \frac{π}{a} ) \qquad ( 21 )$$

$$K 3 = ( - \frac{π}{a} , - \frac{π}{a} ) \qquad ( 22 )$$

$$K 4 = ( \frac{π}{a} , - \frac{π}{a} ) \qquad ( 23 )$$

Here, when the diffraction vector V1 is represented by the following Formula (14), the in-plane wave number vectors K1 to K4 to which the diffraction vector V1 is added are represented by the following formulas (24) to (27).

$$K 1 = ( \frac{π}{a} + Vx , \frac{π}{a} + Vy ) \qquad ( 24 )$$

$$K 2 = ( - \frac{π}{a} + Vx , \frac{π}{a} + Vy ) \qquad ( 25 )$$

$$K 3 = ( - \frac{π}{a} + Vx , - \frac{π}{a} + Vy ) \qquad ( 26 )$$

$$K 4 = ( \frac{π}{a} + Vx , - \frac{π}{a} + Vy ) \qquad ( 27 )$$

Considering that any of the in-plane wave number vectors K1 to K4 falls within the region LL2 in the above-described Formulas (24) to (27), the relationship of the following Formula (28) is established. That is, by adding the diffraction vector V1 that satisfies Formula (28), any of the in-plane wave number vectors K1 to K4 obtained by removing the wave number spread Δk falls within the region LL2. Even in such a case, a part of the +1st-order light and −1st-order light can be outputted.

$${( \pm \frac{π}{a} + Vx )}^{2} + {( \pm \frac{π}{a} + Vy )}^{2} < {( \frac{2 π}{λ} - Δ k )}^{2} \qquad ( 28 )$$

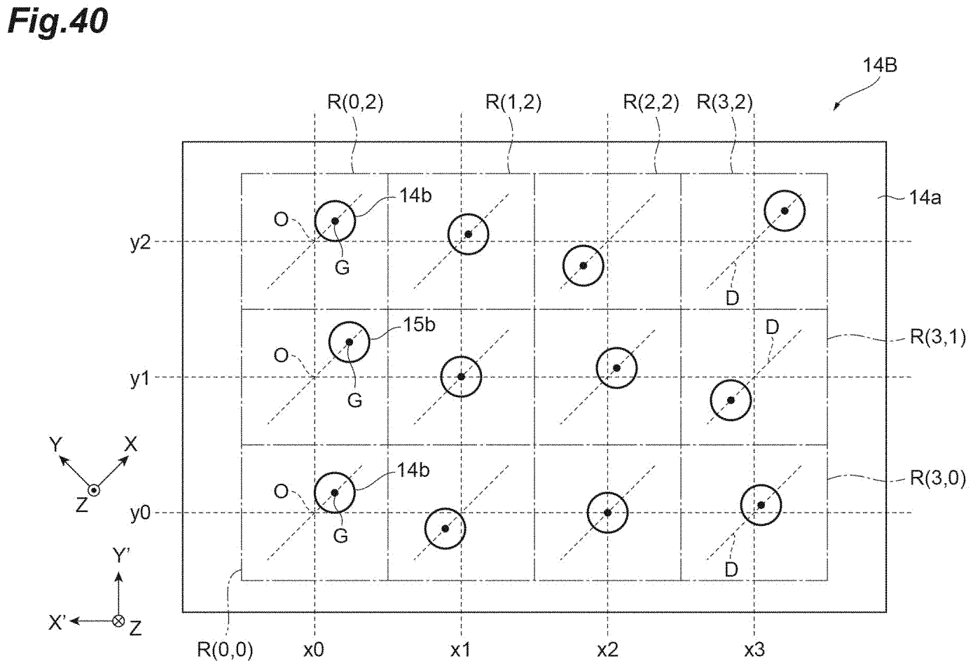

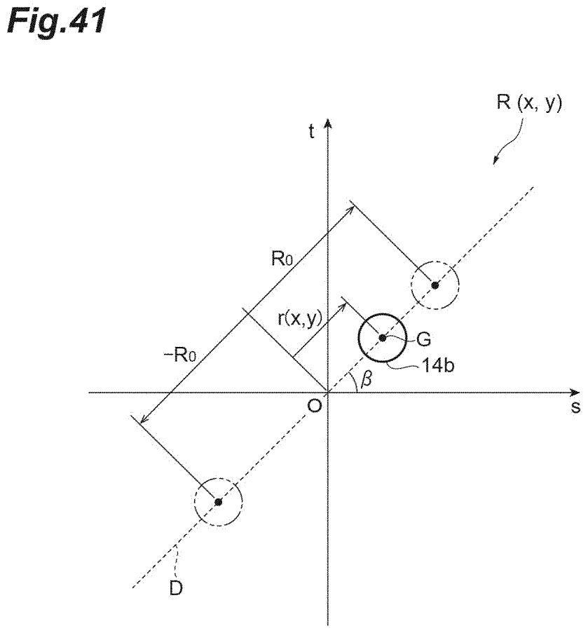

FIG. 40 is a plan view illustrating a resonance mode forming layer 14B as another mode of the resonance mode forming layer of the intensity modulation portion 18. FIG. 41 is a diagram illustrating the arrangement of the modified refractive index region 14b in the resonance mode forming layer 14B of the intensity modulation portion 18. As illustrated in FIGS. 40 and 41, the gravity center G of each of the modified refractive index regions 14b of the resonance mode forming layer 14B may be disposed on a straight line D. The lattice points O of the square lattice are defined by intersection points of lines x0 to x3 parallel to the Y′-axis and lines y0 to y2 parallel to the X′-axis, and similarly to the example of FIG. 32, a square region (square lattice) centered on each of the lattice points O is set as the unit constituent regions R (0, 0) to R (3, 2). The straight line D is a straight line that passes through the lattice point O corresponding to the unit constituent region R (x, y) and is inclined with respect to each side of the square lattice. That is, the straight line D is a straight line inclined with respect to both the X′-axis and the Y′-axis. An inclination angle of the straight line D with respect to one side (X′-axis) of the square lattice is 11

In this case, the inclination angle β is constant in the resonance mode forming layer 14B of the intensity modulation portion 18. The inclination angle β satisfies 0°<β<90°, and in one example, β=45°. Alternatively, the inclination angle β satisfies 180°<β<270°, and in one example, β=225°. In a case where the inclination angle β satisfies 0° <β<90° or 180°<β<270°, the straight line D extends from a first quadrant to a third quadrant of a coordinate plane defined by the X′-axis and the Y′-axis. The inclination angle β satisfies 90°<β<180°, and in one example, β=135°. Alternatively, the inclination angle β satisfies 270°<β<360°, and in one example, β=315°. In a case where the inclination angle β satisfies 90°<β<180° or 270°<β<360°, the straight line D extends from a second quadrant to a fourth quadrant of the coordinate plane defined by the X′-axis and the Y′-axis. As described above, the inclination angle β is an angle excluding 0°, 90°, 180°, and 270°.

Here, in the unit constituent region R (x, y) of which coordinates are defined by the s-axis parallel to the X′-axis and a t-axis parallel to the Y′-axis, a distance between the lattice point O and the gravity center G is r (x, y). x is a position of an x-th lattice point on the X′-axis, and y is a position of a y-th lattice point on the Y′-axis. In a case where the distance r (x, y) is a positive value, the gravity center G is located on the first quadrant (or the second quadrant). In a case where the distance r (x, y) is a negative value, the gravity center G is located on the third quadrant (or the fourth quadrant). In a case where the distance r (x, y) is zero, the lattice point O and the gravity center G coincide with each other. The inclination angles are preferably 45°, 135°, 225°, and 275°. At these inclination angles, only two of the four wave number vectors (for example, the in-plane wave number vector (±π/a, +π/a)) forming the stationary wave at an M point are phase-modulated, and the other two are not phase-modulated. Therefore, a stable stationary wave can be formed.

The distance r (x, y) between the gravity center G of each of the modified refractive index regions and the lattice point O corresponding to each of the unit constituent regions R is individually set for each of the modified refractive index regions 14b according to the phase distribution φ (x, y) in accordance with a desired output light shape. In the present disclosure, such an arrangement mode of the gravity center G is referred to as a second mode. The phase distribution φ (x, y) and a distance distribution r (x, y) have a specific value for each position determined by the values of x and y, but is not necessarily represented by a specific function. A distribution of the distance r (x, y) is determined by extracting the phase distribution φ (x, y) from a complex amplitude distribution obtained by inverse Fourier transforming the desired output light shape.

That is, in a case where a phase φ (x, y) at certain coordinates (x, y) is P₀, the distance r (x, y) is set to zero, in a case where the phase φ (x, y) is π+P₀, the distance r (x, y) is set to the maximum value R₀, and in a case where the phase φ (x, y) is −n+P₀, the distance r (x, y) is set to the minimum value −R₀. For an intermediate phase φ (x, y), the distance r (x, y) is set such that r (x, y)={φ (x, y)−P₀}× R₀/π. An initial phase P₀ can be arbitrarily set.

When the lattice interval of the virtual square lattice is a, the maximum value R₀ of r (x, y) is, for example, within the range of the following Formula (29). When the complex amplitude distribution is obtained from a desired optical image, it is possible to improve reproducibility of the beam pattern by applying an iterative algorithm such as the GS method generally used at the time of calculation for hologram generation.

$$0 \leq {R}_{0} \leq \frac{a}{\sqrt{2}} \qquad ( 29 )$$

In the second mode, a desired output light shape can be obtained by determining the distribution of the distance r (x, y) of the modified refractive index region 14b of the resonance mode forming layer 14B. Under the first to fourth preconditions as in the above-described first mode, the resonance mode forming layer 14B is configured to satisfy the following condition. That is, the corresponding modified refractive index region 14b is disposed in the unit constituent region R (x, y) such that the distance r (x, y) from the lattice point O (x, y) to the gravity center G of the corresponding modified refractive index region 14b satisfies

r(x,y)=C×(φ(x,y)−P₀)

where

C: Proportional constant, for example, R₀/π

P₀: Arbitrary constant, for example, zero.

In a case where it is desired to obtain a desired output light shape, the output light shape may be inverse Fourier transformed to give the distribution of the distance r (x, y) in accordance with the phase φ (x, y) of the complex amplitude to a plurality of the modified refractive index regions 14b. The phase φ (x, y) and the distance r (x, y) may be proportional to each other.

Also in the second mode, similarly to the first mode described above, the lattice interval a of the virtual square lattice and the emission wavelength λ of the active layer 13 satisfy the condition of the M-point oscillation. Moreover, when considering the reciprocal lattice space in the resonance mode forming layer 14B, the magnitude of at least one of the in-plane wave number vectors K1 to K4 in the four directions each including the wave number spread due to the distribution of the distance r (x, y) is smaller than 2π/λ that is, the light line LL.

Also in the second mode, the following action is taken on the resonance mode forming layer 14B in the light emitting device oscillating at the M point, and thus a part of the +1st-order light and −1st-order light is outputted. Specifically, as illustrated in FIG. 36, by adding the diffraction vector V1 having a certain constant magnitude and direction to the in-plane wave number vectors K1 to K4, the magnitude of at least one of the in-plane wave number vectors K1 to K4 becomes smaller than 2π/λ. That is, at least one of the in-plane wave number vectors K1 to K4 to which the diffraction vector V1 is added falls within the light line LL that is a circular region having a radius of 2π/λ. By adding the diffraction vector V1 that satisfies Formula (19) described above, any of the in-plane wave number vectors K1 to K4 falls within the light line LL, and a part of the +1st-order light and −1st-order light are outputted.

Alternatively, as illustrated in FIG. 39, by adding the diffraction vector V1 to a vector obtained by removing the wave number spread Δk from the in-plane wave number vectors K1 to K4 in the four directions (that is, the in-plane wave number vectors in the four directions in a square lattice PCSEL of the M-point oscillation), the magnitude of at least one of the in-plane wave number vectors K1 to K4 in the four directions may be smaller than a value {(2π/λ)−Δk} obtained by subtracting the wave number spread Δk from 2π/λ. That is, by adding the diffraction vector V1 that satisfies Formula (28) described above, any of the in-plane wave number vectors K1 to K4 falls within the region LL2, and a part of the +1st-order light and −1st-order light are outputted.

Operational effects obtained by the light source module 1C according to the present modification example, which is described above, will be described. When a bias current is supplied between the first electrode 21 and the second electrode 22, and between the third electrode 23 and the fourth electrode 24, carriers are collected between the first cladding layer 12 and the second cladding layer 15 in each of the phase synchronization portion 17 and the intensity modulation portion 18, and light is efficiently generated in the active layer 13. The light outputted from the active layer 13 enters the resonance mode forming layer 14A, and resonates in the X-direction and the Y-direction, which are perpendicular to the thickness direction in the resonance mode forming layer 14A. This light becomes a phase-aligned coherent laser light beam in the resonance mode forming layer 14A of the phase synchronization portion 17.

A portion of the resonance mode forming layer 14A constituting a part of the intensity modulation portion 18 is arranged in the Y-direction with respect to a portion of the resonance mode forming layer 14A constituting a part of the phase synchronization portion 17. Therefore, the phase of the laser light beam in the resonance mode forming layer 14A of each subpixel Pb coincides with the phase of the laser light beam in the resonance mode forming layer 14A of the phase synchronization portion 17. As a result, the phases of the laser light beams in the resonance mode forming layer 14A are aligned between the subpixels Pb.

The resonance mode forming layer 14A of the present modification example causes oscillation at the M-point, but in the resonance mode forming layer 14A of the intensity modulation portion 18, a distribution form of a plurality of the modified refractive index regions 14b satisfies a condition for the laser light beam L to be outputted from the intensity modulation portion 18 in a direction intersecting both the X-direction and the Y-direction. Therefore, the phase-aligned laser light beam L is outputted from each subpixel Pb of the intensity modulation portion 18 in a direction intersecting both the X-direction and the Y-direction (for example, a direction inclined with respect to the Z-direction). A part of the laser light beam L directly reaches the semiconductor substrate 11 from the resonance mode forming layer 14A. Furthermore, the rest of the laser light beam L reaches the third electrode 23 from the resonance mode forming layer 14A, is reflected by the third electrode 23, and then reaches the semiconductor substrate 11. The laser light beam L passes through the semiconductor substrate 11, and exits from the back surface 11b of semiconductor substrate 11 to the outside of the light source module 1C through the opening 24a of the fourth electrode 24.

Also in the present modification example, the third electrode 23 is provided in correspondence with each subpixel Pb. Therefore, the magnitude of the bias current supplied to the intensity modulation portion 18 can be individually adjusted for each subpixel Pb. That is, the light intensity of the laser light beam L outputted from the intensity modulation portion 18 can be adjusted individually (independently) for each subpixel Pb. Furthermore, in each pixel Pa, the length Da of the region including consecutive N₂ subpixels Pb in the arrangement direction (X-direction) (see FIG. 27 and FIG. 30) is smaller than the emission wavelength Δ of the active layer 13, that is, the wavelength of the laser light beam L. As described in the above-described embodiment, in a case where the subpixels Pb that output light at the same time are limited to the consecutive N₂ subpixels Pb among the N₁ subpixels Pb constituting each pixel Pa, each pixel Pa can be regarded as a pixel having a single phase equivalently. In a case where the phases of the laser light beams L outputted from the N₁ subpixels Pb constituting each pixel Pa are aligned with each other, the phase of the laser light beam L outputted from each pixel Pa is determined according to an intensity distribution realized by the N₁ subpixels Pb constituting the pixel Pa. Therefore, also in the light source module 1C of the present modification example, the phase distribution of the laser light beam L can be dynamically controlled. Note that the above-described effect can be obtained in a similar manner also in a case where the resonance mode forming layer 14B is provided instead of the resonance mode forming layer 14A.

As in the present modification example, the resonance mode forming layer 14A (or 14B) included in the phase synchronization portion 17 may have a photonic crystal structure in which a plurality of the modified refractive index regions 14b are periodically disposed. In this case, the phase-aligned laser light beam can be supplied from the phase synchronization portion 17 to each subpixel Pb.

As in the present modification example, a condition for the laser light beam L to be outputted in a direction intersecting both the X-direction and the Y-direction from the intensity modulation portion 18 may be that the in-plane wave number vectors K1 to K4 in the four directions each including a wave number spread corresponding to an angular spread of the laser light beam L outputted from the intensity modulation portion 18 are formed on an reciprocal lattice space of the resonance mode forming layer 14A (or 14B), and the magnitude of at least one in-plane wave number vector is smaller than 2π/λ, that is, the light line LL. As described above, normally, in a stationary wave state of the M-point oscillation, the light propagated in the resonance mode forming layer 14A (or 14B) is totally reflected, and the output of both a signal light (for example, at least one of the +1st-order light and −1st-order light) and the 0th-order light is suppressed. On the other hand, in an S-iPM laser, the in-plane wave number vectors K1 to K4 as described above can be adjusted by considering the arrangement of each modified refractive index region 14b. In a case where the magnitude of at least one in-plane wave number vector is smaller than 2π/λ, the in-plane wave number vector has a component in the thickness direction (Z-direction) of the resonance mode forming layer 14A (or 14B) and does not cause total reflection at an interface with air. As a result, a part of the signal light as the laser light beam L can be outputted from each pixel Pa.

### Fourth Modification Example

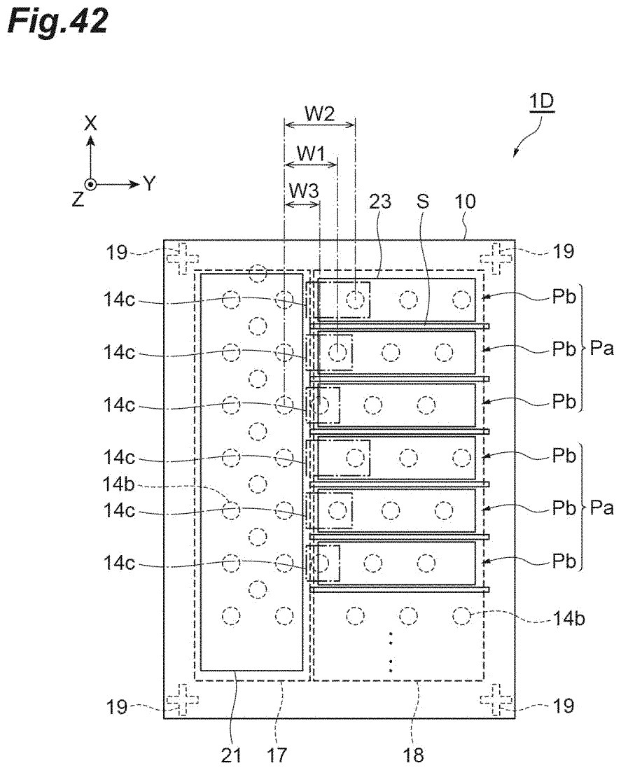

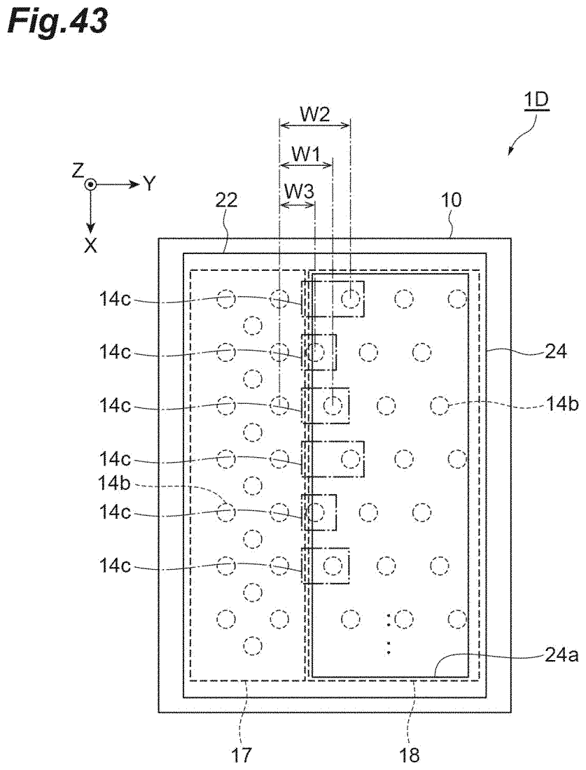

FIG. 42 is a plan view of a light source module 1D according to the fourth modification example of the above-described embodiment. FIG. 43 is a bottom view of the light source module 1D. Note that a cross-sectional configuration of the light source module 1D is similar to that of the above-described third modification example, and is thus will not be illustrated.

A difference between the present modification example and the third modification example is a structure of the resonance mode forming layer 14A (or 14B) in the intensity modulation portion 18. That is, in the present modification example, similarly to the above-described second modification example, the phase shift portion 14c for making phases of the laser light beams L outputted from the pixels Pa in the Y-direction different from each other between N₁ subpixels Pb is included in the resonance mode forming layer 14A (or 14B) of each subpixel Pb. Details of the phase shift portion 14c are similar to those of the second modification example.

As in the present modification example, the phase shift portion 14c for making phases of the laser light beams L outputted from the pixels Pa in the Y-direction different from each other between N₁ subpixels Pb may be included in the resonance mode forming layer 14A (or 14B) of each subpixel Pb. In this case, the phase of the laser light beam L outputted from each pixel Pa is different for each subpixel Pb. The phase of the laser light beam L outputted from each pixel Pa is determined in accordance with the intensity distribution and the phase distribution of N₁ subpixels Pb constituting the pixel Pa. Therefore, the degree of freedom of controlling the phase distribution of the laser light beam L can be further increased.

The light source module according to the present disclosure is not limited to the above-described embodiment, and various other modifications can be made. For example, in the above-described embodiment and each modification example, an example in which a plurality of pixels Pa are arranged one-dimensionally has been described, but a plurality of the pixels Pa may be arranged two-dimensionally. In this case, for example, a plurality of the light source modules disclosed in the above-described embodiment or each modification example may be combined. Furthermore, in the above-described embodiment, an example in which the semiconductor stack portion 10 mainly includes a GaAs-based semiconductor has been described, but the semiconductor stack portion 10 may mainly include an InP-based semiconductor or may mainly include a GaN-based semiconductor.

### REFERENCE SIGNS LIST

| | |
|---|---|
| 1A to 1D | Light source module |
| 10 | Semiconductor stack portion |
| 11 | Semiconductor substrate (included in first |
| | conductivity type semiconductor layer) |
| 11a | Main surface |
| 11b | Back surface |
| 12 | First cladding layer (included in first conductivity |
| | type semiconductor layer) |
| 13 | Active layer |
| 14 | Photonic crystal layer |
| 14A, 14B | Resonance mode forming layer |
| 14a | Base layer |
| 14b | Modified refractive index region |
| 14c | Phase shift portion |
| 15 | Second cladding layer (included in second |
| | conductivity type semiconductor layer) |
| 16 | Contact layer (included in Second conductivity |
| | type semiconductor layer) |
| 17 | Phase synchronization portion |
| 18 | Intensity modulation portion |
| 19 | Mark |
| 21 | First electrode |
| 22 | Second electrode |
| 23 | Third electrode |
| 24 | Fourth electrode |
| 24a | Opening |
| 25 | Antireflection film |
| 30 | Control circuit board |
| 31 | Conductive bonding material |
| B1 | Basic reciprocal lattice vector |
| D | Straight line |
| G | Gravity center |
| K1 to K4, Ka, Kb | In-plane wave number vector |
| L | Laser light beam |
| La | Light emission point |
| LL | Light line |
| LL2 | Region |
| O | Lattice point |
| Pa | Pixel |
| Pb | Subpixel |
| R | Unit constituent region |
| S, SA | Slit |
| SP | Wave number spread |
| SW | Synthesized wave front |
| V1 | Diffraction vector |
| WF1 to WF3 | Wave front |

1. A light source module comprising:
a semiconductor stack portion configured to include a first conductivity type semiconductor layer, a second conductivity type semiconductor layer, and a stacked body disposed between the first conductivity type semiconductor layer and the second conductivity type semiconductor layer and including an active layer and a photonic crystal layer that causes Γ-point oscillation, in which a phase synchronization portion and an intensity modulation portion, which are arranged in a first direction that is one of resonance directions of the photonic crystal layer, are provided, a portion of the stacked body constituting at least a part of the intensity modulation portion has M (M is an integer of two or more) pixels arranged in a second direction intersecting the first direction, each of the M pixels has N₁ (N₁ is an integer of two or more) subpixels arranged in the second direction, and a length of a region including consecutive N₂ (N₂ is an integer of two or more and N₁ or less) subpixels among the N₁ subpixels, which is defined in the second direction, is smaller than an emission wavelength λ of the active layer;
a first electrode configured to be electrically connected to a portion of the first conductivity type semiconductor layer configuring at least a part of the phase synchronization portion;
a second electrode configured to be electrically connected to a portion of the second conductivity type semiconductor layer constituting at least a part of the phase synchronization portion;
a third electrode configured to be provided in one-to-one correspondence with the N₁ subpixels, and electrically connected to one of the portion of the first conductivity type semiconductor layer and the portion of the second conductivity type semiconductor layer which constitute at least a part of the intensity modulation portion; and
a fourth electrode configured to be electrically connected to the other one of the portion of the first conductivity type semiconductor layer and the portion of the second conductivity type semiconductor layer which constitute at least a part of the intensity modulation portion,
wherein light is outputted from each of the M pixels included in the intensity modulation portion in a direction intersecting both the first direction and the second direction.

2. The light source module according to claim 1,
wherein the photonic crystal layer includes a phase shift portion provided in one-to-one correspondence with the N₁ subpixels, the phase shift portion being configured to make phases of light beams outputted from the M pixels in the first direction different from each other between the N₁ subpixels.

3. A light source module comprising:
a semiconductor stack portion configured to include a first conductivity type semiconductor layer, a second conductivity type semiconductor layer, and a stacked body disposed between the first conductivity type semiconductor layer and the second conductivity type semiconductor layer and including an active layer and a resonance mode forming layer, in which a phase synchronization portion and an intensity modulation portion, which are arranged in a first direction that is one of resonance directions of the resonance mode forming layer, are provided, a portion of the stacked body constituting at least a part of the intensity modulation portion has M (M is an integer of two or more) pixels arranged in a second direction intersecting the first direction, each of the M pixels has N₁ (N₁ is an integer of two or more) subpixels arranged in the second direction, and a length of a region including consecutive N₂ (N₂ is an integer of two or more and N₁ or less) subpixels among the N₁ subpixels, which is defined in the second direction, is smaller than an emission wavelength λ of the active layer;
a first electrode configured to be electrically connected to a portion of the first conductivity type semiconductor layer constituting at least a part of the phase synchronization portion;
a second electrode configured to be electrically connected to a portion of the second conductivity type semiconductor layer constituting at least a part of the phase synchronization portion;
a third electrode configured to be provided in one-to-one correspondence with the N₁ subpixels, and electrically connected to one of the portion of the first conductivity type semiconductor layer and the portion of the second conductivity type semiconductor layer which constitute at least a part of the intensity modulation portion; and
a fourth electrode configured to be electrically connected to the other one of the portion of the first conductivity type semiconductor layer and the portion of the second conductivity type semiconductor layer which constitute at least a part of the intensity modulation portion,
wherein the resonance mode forming layer includes a base layer and a plurality of modified refractive index regions having a refractive index different from a refractive index of the base layer and distributed two-dimensionally on a plane perpendicular to a thickness direction of the resonance mode forming layer,
an arrangement of the plurality of modified refractive index regions satisfies a condition of an M-point oscillation,
in a virtual square lattice set on the plane of a portion of the resonance mode forming layer constituting at least a part of the intensity modulation portion, a gravity center of each of the plurality of modified refractive index regions is disposed at a position away from a corresponding lattice point among lattice points of the virtual square lattice and each of the plurality of modified refractive index regions is disposed in any one of a first mode in which an angle of a vector connecting the corresponding lattice point with the gravity center with respect to the virtual square lattice is individually set and a second mode in which the gravity center is disposed on a straight line passing through the corresponding lattice point and inclined with respect to the square lattice, and a distance between the gravity center and the corresponding lattice point is individually set, and
a distribution of the angle of the vector in the first mode or a distribution of the distance in the second mode satisfies a condition for light to be outputted from the intensity modulation portion in a direction intersecting both the first direction and the second direction.

4. The light source module according to claim 3,
wherein the portion of the resonance mode forming layer constituting at least a part of the phase synchronization portion has a photonic crystal structure in which the plurality of modified refractive index regions are periodically disposed.

5. The light source module according to claim 3,
wherein the resonance mode forming layer includes a phase shift portion provided in one-to-one correspondence with the N₁ subpixels, the phase shift portion being configured to make phases of light beams outputted from the M pixels in the first direction different from each other between the N₁ subpixels.

6. The light source module according to claim 3,
wherein the condition for light to be outputted from the intensity modulation portion in a direction intersecting both the first direction and the second direction is that in-plane wave number vectors in four directions each including a wave number spread corresponding to angular spread of the light outputted from the intensity modulation portion are formed on an reciprocal lattice space of the resonance mode forming layer, and a magnitude of at least one in-plane wave number vector among the in-plane wave number vectors in the four directions is smaller than 2π/λ.

7. The light source module according to claim 1,
wherein the first electrode covers an entire surface of the portion of the first conductivity type semiconductor layer in a state of being in contact with the portion of the first conductivity type semiconductor layer constituting at least a part of the phase synchronization portion, and
the second electrode covers an entire surface of the portion of the second conductivity type semiconductor layer in a state of being in contact with the portion of the second conductivity type semiconductor layer constituting at least a part of the phase synchronization portion.

8. The light source module according to claim 1,
wherein the third electrode is in contact with one of the portion of the first conductivity type semiconductor layer and the portion of the second conductivity type semiconductor layer which constitute at least a part of the intensity modulation portion,
the fourth electrode has a frame shape surrounding an opening for allowing light to pass through, and is in contact with the other one of the portion of the first conductivity type semiconductor layer and the portion of the second conductivity type semiconductor layer which constitute at least a part of the intensity modulation portion.

9. The light source module according to claim 1,
wherein the semiconductor stack portion includes a plurality of slits, and the N₁ subpixels and the plurality of slits are alternately arranged one by one in the second direction.

10. The light source module according to claim 1,
wherein the N₁ subpixels include three or more subpixels, and the N₂ subpixels include three or more subpixels.

11. The light source module according to claim 3,
wherein the first electrode covers an entire surface of the portion of the first conductivity type semiconductor layer in a state of being in contact with the portion of the first conductivity type semiconductor layer constituting at least a part of the phase synchronization portion, and
the second electrode covers an entire surface of the portion of the second conductivity type semiconductor layer in a state of being in contact with the portion of the second conductivity type semiconductor layer constituting at least a part of the phase synchronization portion.

12. The light source module according to claim 3,
wherein the third electrode is in contact with one of the portion of the first conductivity type semiconductor layer and the portion of the second conductivity type semiconductor layer which constitute at least a part of the intensity modulation portion,
the fourth electrode has a frame shape surrounding an opening for allowing light to pass through, and is in contact with the other one of the portion of the first conductivity type semiconductor layer and the portion of the second conductivity type semiconductor layer which constitute at least a part of the intensity modulation portion.

13. The light source module according to claim 3,
wherein the semiconductor stack portion includes a plurality of slits, and the N₁ subpixels and the plurality of slits are alternately arranged one by one in the second direction.

14. The light source module according to claim 3,
wherein the N₁ subpixels include three or more subpixels, and the N₂ subpixels include three or more subpixels.
